(19) United States
(12) Patent Application Publication
(10) Pub. No.: US 2026/0013064 A1
(43) Pub. Date: Jan. 8, 2026

(54) COUPLING MEMBER AND POWER ELECTRONIC DEVICE INCLUDING SAME

(71) Applicant: LS ELECTRIC CO., LTD., Anyang-si, Gyeonggi-do (KR)

(72) Inventor: Su Hyeong LEE, Anyang-si, Gyeonggi-do (KR)

(21) Appl. No.: 18/993,811

(22) PCT Filed: Jul. 20, 2023
(86) PCT No.: PCT/KR2023/010491

§ 371 Date: Jan. 13, 2025

(30) Foreign Application Priority Data
Aug. 19, 2022 (KR) 10-2022-0103721

(51) Int. Cl. H05K 7/14

(52) U.S. Cl. CPC H05K 7/1474; H05K 7/1465; H05K 7/1475

(57) ABSTRACT

Disclosed are a coupling member and a power electronic device including same. A coupling member according to an aspect of the present disclosure is a coupling member that is removably coupled to an external power electronic device, and includes: a coupling body; and a coupling arm that extends from one side of the coupling body in the height direction and is removably coupled to the power electronic device, wherein the coupling arm includes a coupling extension portion extending from the one side of the coupling body into the inside of the power electronic device and a coupling protrusion that protrudes from an end of the coupling extension portion and is coupled to an inner surface of the power electronic device, wherein a plurality of coupling arms are provided, and the plurality of coupling arms may be arranged to be spaced apart from each other along one direction.

### CROSS-REFERENCE TO RELATED APPLICATIONS

The present application is a National Stage of International Application No. PCT/KR2023/010491, filed on Jul. 20, 2023, which claims priority to Korean Application No. 10-2022-0103721, filed Aug. 19, 2022, the entire contents of each hereby incorporated by reference.

### FIELD

The present disclosure relates to a coupling member and a power electronic device including the same, and more specifically, to a coupling member having a structure capable of easily coupling a power electronic device and a terminal member that communicates with and is electrically connected to the power electronic device, and a power electronic device including the same.

### BACKGROUND

A programmable logic circuit (PLC), which is a type of power electronic device, is a programmable logic control device that is widely used for automatic control of devices and process control for performing intermittent operations. A PLC includes a printed circuit board (PCB) for processing control signals, a capacitor for supplying power to the PCB, and the like.

A conventional PLC is provided as a single device and only provides preset power capacity. However, recently, PLCs have been provided in a modular form adopting a configuration in which power capacity varies according to the number of provided power electronic devices. For this purpose, a plurality of provided PLCs are connected to a device called a base.

By providing PLCs in a modular form, not only may power capacity be varied, but also a problematic PLC alone may be separated from a plurality of PLCs, repaired, and then coupled to a base again. Accordingly, the popularity of modular PLCs is increasing.

However, since a PLC is detachably coupled to a base, various problems are occurring, unlike in the past when a PLC was fixedly coupled to a base.

First, since a PLC and a base are incompletely connected, there is a risk of the PLC and the base being damaged and arbitrarily separated. In addition, there is a risk of a portion, at which a PLC and a base are connected, being damaged due to a worker's inexperience.

Meanwhile, when a PLC provided as a module is to be repaired, a cover of the PLC should be removed to replace a problematic part.

Considering that a cover of a PLC is usually formed as an integral type to maintain rigidity, when the cover is separated and reassembled for repair of a corresponding part, it is difficult to maintain the same rigidity as before repair. Accordingly, since excessive time and costs are required for maintenance, there is a risk that work convenience and user satisfaction can be reduced.

Furthermore, when a cover of a PLC cover is provided as an integral type, due to vibrations generated during operation of the PLC and a base or shock generated when the PLC and the base are coupled or separated, excessive stress may be generated in a coupling portion between the PLC and the base. In this case, the possibility of damage to the corresponding portion also increases, and when the cover of the PLC is formed as an integral type, the entire cover should be replaced to repair the corresponding portion.

In addition, when a component of a PLC and a cover are provided as an integral type, a component such as a PCB should also be separated to replace the cover. Accordingly, there is a risk that the component of the PLC may be damaged and the operational reliability thereof can be reduced during reassembly.

Korean Patent Registration Document No. 10-1342513 discloses an assembly-type base for an electronic power meter. Specifically, it discloses an assembly base for an electronic power meter in which a terminal block is provided such that an input side terminal block and an output side terminal block are assemblable or detachable, thereby allowing the power capacity of a power meter to be varied.

However, the assembly-type base for the electronic power meter disclosed in the related art document only provides a method of detachably coupling the input/output side terminal blocks in an assembly manner to vary the power capacity. That is, the related art document does not provide a method of preventing damage that may occur in the terminal block or the assembly-type base due to shock generated when the input/output side terminal blocks and the assembly-type base are coupled and separated.

Korean Patent Registration Document No. 10-1011034 discloses a modular measuring instrument integration system in which a case of a measuring circuit is modularized. Specifically, it disclosed a modular measuring instrument integration system in which a measuring instrument is modularized and detachably mounted on a base to modularize the case of the measuring circuit in which the number of measuring instrument modules may be varied.

However, the modular measuring instrument integration system in which the case of the measuring circuit is modularized disclosed in the related art document requires a separate guide for supporting coupled measuring instrument modules. In addition, a base module is configured to support a measuring module at a lower side, and the related art document has a limitation in that it is difficult to apply the base module in other directions such as an anteroposterior direction or a lateral direction.

Furthermore, the related art documents do not provide a method of maintaining a coupling state between the PLC and the base by attenuating vibrations generated during the operation of the PLC.
Korean Patent Registration Document No. 10-1342513 (Jan. 2, 2014)
Korean Patent Registration Document No. 10-1011034 (Jan. 26, 2011)

### SUMMARY

The present disclosure is to solve the above problems and is directed to providing a coupling member having a structure in which a power electronic device and a terminal member may be coupled by a separate member, and a power electronic device including the same.

The present disclosure is also directed to providing a coupling member having a structure capable of preventing damage to a power electronic device, and a power electronic device including the same.

The present disclosure is also directed to providing a coupling member having a structure capable of preventing damage to a power electronic device due to vibrations, and a power electronic device including the same.

The present disclosure is also directed to providing a coupling member having a structure capable of preventing the arbitrary movement of a power electronic device, and a power electronic device including the same.

The present disclosure is also directed to providing a coupling member having a structure in which a coupling state between a power electronic device and a terminal member can be stably maintained, and a power electronic device including the same.

However, the objects of the present disclosure are not limited to those described above, and other objects that are not described will be clearly understood by a person skilled in the art from the description below.

### Technical Solution

According to one aspect of the present disclosure, there is provided a coupling member detachably connected to an external power electronic device includes a coupling body, and a coupling arm which extends from one side of the coupling body in a height direction and is detachably coupled to the power electronic device, wherein the coupling arm includes a coupling extension portion extending from the one side of the coupling body to an interior of the power electronic device, and a coupling protrusion protruding from an end portion of the coupling extension portion and coupled to an inner surface of the power electronic device, and the coupling arm is provided as a plurality of coupling arms, wherein the plurality of coupling arms are disposed apart from each other in one direction.

In this case, there may be provided the coupling member in which the coupling arm includes a first coupling arm positioned to be biased to one side of the coupling body in a length direction, and a second coupling arm positioned to be biased to the other side opposite to the one side of the coupling body in the length direction.

In addition, there may be provided the coupling member in which the first coupling protrusion of the first coupling arm protrudes toward the one side in the length direction, and the second coupling protrusion of the second coupling arm protrudes toward the other side in the length direction.

In addition, there may be provided the coupling member in which the coupling arm is hook-fitted to the power electronic device.

In addition, there may be provided the coupling member including a support arm which obliquely extends from the one side of the coupling body in a length direction toward the power electronic device and of which an end portion in an extending direction thereof is positioned to protrude further than an end portion of the one side of the coupling body in the height direction to elastically support the coupling body.

In addition, there may be provided the coupling member in which the support arm includes a first support arm positioned to be biased to one side of the coupling body in a width direction, and a second support arm disposed apart from the first support arm and positioned to be biased to the other side of the coupling body in the width direction.

In addition, there may be provided the coupling member including a plurality of guide grooves formed to pass through each side surface of the coupling body in a width direction to movably accommodate guide plates provided in the power electronic device, and a guide rib which is positioned between the plurality of guide grooves, extends from an interior of the coupling body in the height direction of the coupling body, and is inserted into a rib accommodation portion provided in the power electronic device.

In this case, there may be provided the coupling member in which the coupling body includes a first coupling body extending in the height direction, a second coupling body which is continuous with one side of the first coupling body in a length direction and extends in the length direction, and a coupling protrusion which is positioned at an end portion of the second coupling body and protrudes to the other side in the height direction.

In addition, there may be provided the coupling member in which the coupling protrusion includes a first support surface obliquely extending to the other side in the height direction, and a second support surface which is continuous with the first support surface and obliquely extends to the one side in the height direction, and the coupling body includes a pressing groove formed to be recessed in the second support surface.

In addition, there is provided a power electronic device including a housing having a space formed therein, a coupling member attachment-detachment portion positioned at a rear upper side of the housing, and a coupling member detachably coupled to the coupling member attachment-detachment portion, wherein the coupling member attachment-detachment portion includes a coupling member accommodation portion of which an upper side and a rear side are open and which is partially surrounded by an upper surface of the housing, and a coupling opening formed to pass through the upper surface of the housing, and the coupling member includes a coupling body accommodated in the coupling member accommodation portion, and a coupling arm which extends from a lower side of the coupling body and passes through and is coupled to the coupling opening.

In this case, there may be provided the power electronic device in which the coupling opening includes a first coupling opening positioned to be biased to a front side of the coupling member accommodation portion, and a second coupling opening positioned to be biased to a rear side of the coupling member accommodation portion, and the coupling arm includes a first coupling arm which is positioned to be biased to a front side of the coupling body and passes through the first coupling opening, and a second coupling arm which is positioned to be biased to a rear side of the coupling body and passes through the second coupling opening.

In addition, there may be provided the power electronic device in which the first coupling arm includes a first coupling extension portion which is continuous with the coupling body and passes through the first coupling opening, and a first coupling protrusion which is positioned at an end portion of the first coupling extension portion, is formed to protrude forward, and is coupled to an upper inner surface of the housing, and the second coupling arm includes a second coupling extension portion which is continuous with the coupling body and passes through the second coupling opening, and a second coupling protrusion which is positioned at an end portion of the second coupling extension portion is formed to protrude rearward, and is coupled to the upper inner surface of the housing.

In this case, there may be provided the power electronic device in which the coupling member includes a support arm which is continuous with a rear side of the coupling body, obliquely extends downwardly rearward such that a lower end portion thereof protrudes downward further than a lower end portion of the coupling body, and elastically supports the coupling body, the coupling body is spaced apart from the upper surface of the housing, and the support arm is in contact with the upper surface of the housing.

In addition, there may be provided the power electronic device in which the coupling member attachment-detachment portion includes a guide plate which vertically protrudes, laterally extends, and is formed to have a thickness in an anteroposterior direction, and the coupling member includes a guide groove formed to pass through a surface of the coupling body in a lateral direction, vertically extends, and movably accommodates the guide plate.

In this case, there may be provided the power electronic device in which the guide plate includes a first guide plate positioned to be biased to one side in the lateral direction, and a second guide plate positioned to be biased to the other side in the lateral direction and positioned apart from the first guide plate, and the guide groove includes a first guide groove formed to vertically pass through a left surface of the coupling body to movably accommodate the first guide plate, and a second guide groove formed to vertically pass through a right surface of the coupling body to movably accommodate the second guide plate.

In addition, there may be provided the power electronic device in which the coupling member attachment-detachment portion includes a rib accommodation portion formed between the first guide plate and the second guide plate, and the coupling member includes a plate accommodation groove which is formed to be recessed in a lower side of the coupling body, accommodates the first guide plate and the second guide plate, and communicates with the first guide groove and the second guide groove, and a guide rib which is positioned in the plate accommodation groove, extends in an anteroposterior direction and a vertical direction, and is accommodated in the rib accommodation portion.

In this case, there may be provided the power electronic device in which the coupling body includes a first coupling body that extends vertically, a second coupling body which is continuous with the first coupling body and extends in an anteroposterior direction, and a coupling protrusion which is positioned at a rear end portion of the second coupling body, protrudes upward, and is coupled to a support member provided in an external terminal member.

In addition, there may be provided the power electronic device in which the coupling protrusion includes a first support surface which forms a front surface thereof and obliquely extends upwardly rearward, and a second support surface which forms a rear surface thereof, is continuous with the first support surface, and obliquely extends downwardly rearward, and the support member of the terminal member includes a first extension arm extending forward, and a second extension arm which is positioned at a front end portion of the first extension arm, protrudes toward the coupling protrusion, and is hook-fitted to the coupling protrusion.

In this case, there may be provided the power electronic device in which the coupling body includes a pressing groove formed to be recessed in the second support surface.

In addition, there may be provided the power electronic device in which the coupling body includes a first coupling body that extends vertically, and a pressing protrusion formed to protrude upward from an upper end portion of the first coupling body, wherein the pressing protrusion is exposed to the outside of a support member provided in an external terminal member and hook-fitted to the coupling member.

According to such a configuration, in a coupling member and a power electronic device including the same according to embodiments of the present disclosure, the power electronic device and a terminal member can be coupled by a separate member.

A coupling member is provided in the power electronic device. The coupling member is detachably coupled to a coupling member attachment-detachment portion provided in the power electronic device. The coupling member includes a coupling arm extending toward the power electronic device. The coupling member attachment-detachment portion includes a coupling opening which is formed to pass through an upper surface of a housing and through which the coupling arm is withdrawably coupled.

The coupling arm includes a coupling extension portion which extends toward the coupling opening and passes through and is coupled to the coupling opening, and a coupling protrusion which protrudes outward from an end portion of the coupling extension portion and is hook-fitted to the coupling opening.

Therefore, when the coupling member and the coupling member attachment-detachment portion are coupled, the coupling member and the housing of the power electronic device may be detachably coupled.

Meanwhile, the coupling member includes a coupling body forming a body and a coupling protrusion continuous with the coupling body. The coupling protrusion protrudes upward.

The terminal member to which the coupling member is detachably coupled includes a support member. The support member includes a first extension arm extending forward and a second extension arm extending from an end portion of the first extension arm to the coupling member.

When the power electronic device to which the coupling member is coupled is moved toward the terminal member, the second extension arm is pressed by the coupling protrusion and deformed upward to store a restoring force. When the coupling protrusion passes the second extension arm, the second extension arm is restored to its original shape by the restoring force and is hook-fitted to the coupling protrusion.

Accordingly, the power electronic device and the terminal member can be detachably coupled by one coupling member.

In addition, according to such a configuration, in the coupling member and the power electronic device including the same according to the embodiment of the present disclosure, it is possible to prevent damage to the power electronic device.

As described above, the power electronic device and the terminal member are detachably connected through the coupling member. Therefore, when damage occurs in the coupling member, maintenance can be performed after only the coupling member is removed. That is, for maintenance of the coupling member, the disassembly of components of the power electronic device is not required.

Accordingly, only the coupling member can be separated to perform maintenance, and thus damage to the components of the power electronic device can be prevented.

In addition, according to such a configuration, in the coupling member and the power electronic device including the same according to the embodiment of the present disclosure, it is possible to prevent damage to the power electronic device due to vibrations.

The coupling member includes a support arm. The support arm is positioned at a lowermost portion among portions of the coupling member. In other words, when the coupling member is coupled to the power electronic device, the support arm is positioned at a lowermost portion among portions exposed to the outside. Thus, the support arm is in contact with an upper surface of the housing and elastically supports other components of the coupling member.

When the power electronic device or the terminal member is operated, and vibrations are generated, the support arm is pressed and deformed to store an elastic force. Accordingly, the vibrations of the power electronic device are buffered, and shock caused by the vibrations transmitted to the components of the power electronic device can be minimized.

Therefore, damage to the components of the power electronic device due to vibrations can be prevented.

In addition, according to such a configuration, the coupling member and the power electronic device including the same according to the embodiment of the present disclosure can be prevented from arbitrarily moving.

The coupling member includes a guide portion. The guide portion is formed to pass through each of a left surface and a right surface of the coupling body and includes a plurality of guide grooves that extend vertically. A plurality of guide plates provided in the coupling member attachment-detachment portion are movably accommodated in the plurality of guide grooves. Due to coupling between the guide plates and the guide grooves, the arbitrary anteroposterior movement of the power electronic device can be prevented.

In addition, the guide portion includes a plate accommodation groove which is a space formed to be recessed into the coupling body. The plate accommodation groove includes a guide rib formed to extend in an anteroposterior direction and a vertical direction. The coupling member attachment-detachment portion includes a rib accommodation portion which is a space formed between the plurality of guide plates spaced apart from each other. The guide rib is accommodated in the rib accommodation portion and is laterally restrained by the plurality of guide plates. Due to coupling between the guide rib and the rib accommodation portion, the arbitrary lateral movement of the power electronic device can be prevented.

Therefore, the arbitrary random movement of the power electronic device can be prevented.

In addition, according to such a configuration, in the coupling member and the power electronic device including the same according to embodiments of the present disclosure, a coupling state between the power electronic device and the terminal member can be stably maintained.

Due to such a configuration, the coupling member is hook-fitted to each of the power electronic device and the terminal member. The coupling member is not arbitrarily separated from the power electronic device or the terminal member unless an external force in a predetermined direction is applied.

In addition, the coupling member includes a support arm. The support arm is configured to buffer vertical vibrations applied to the power electronic device. Accordingly, coupling states of the power electronic device and the terminal member with the coupling member can be stably maintained.

Furthermore, the coupling member is provided with a guide portion, and a member guide portion is coupled to the coupling member attachment-detachment portion. Due to coupling between the guide portion and the member guide portion, the arbitrary movement of the power electronic device in an anteroposterior direction and a lateral direction is prevented.

Accordingly, the coupling member can be stably coupled to the power electronic device and the terminal member, vertical vibrations can be buffered, and arbitrary movement in an anteroposterior direction and a lateral direction can be prevented. As a result, coupling states between the coupling member, the power electronic device, and the terminal member can be stably maintained.

The effects of the present disclosure are not limited to the above effects and should be understood to include all effects that may be inferred from the configuration of the present disclosure described in the detailed description or claims of the present disclosure.

### BRIEF DESCRIPTION OF THE DRAWINGS

FIG. 1 is a perspective view illustrating a state in which a terminal member and a power electronic device are coupled according to an embodiment of the present disclosure.

FIG. 2 is a perspective view illustrating a state in which the terminal member and the power electronic of FIG. 1 are separated.

FIG. 3 is a front view illustrating the terminal member of FIG. 1.

FIG. 4 is a partially enlarged perspective view illustrating the terminal member of FIG. 1.

FIG. 5 is a cross-sectional side view illustrating the terminal member of FIG. 1.

FIG. 6 is a perspective view illustrating the power electronic device of FIG. 1.

FIG. 7 is a partially enlarged perspective view illustrating the power electronic device of FIG. 6.

FIG. 8 is a partially enlarged plan view illustrating the power electronic device of FIG. 6.

FIGS. 9 and 10 are perspective views illustrating a coupling member provided in the power electronic device of FIG. 1.

FIG. 11 is a front view illustrating the coupling member provided in the power electronic device of FIG. 1.

FIG. 12 is a rear view illustrating the coupling member provided in the power electronic device of FIG. 1.

FIG. 13 is a plan view illustrating the coupling member provided in the power electronic device of FIG. 1.

FIG. 14 is a bottom view illustrating the coupling member provided in the power electronic device of FIG. 1.

FIG. 15 is a right side view illustrating the coupling member provided in the power electronic device of FIG. 1.

FIGS. 16 to 20 are use state views illustrating a process of coupling the coupling member of FIG. 9 to the power electronic device of FIG. 6 and a coupling state.

FIGS. 21 to 23 are use state views illustrating a process of coupling the power electronic device and the terminal member of FIG. 1 and a coupling state.

### DETAILED DESCRIPTION

Hereinafter, embodiments of the present disclosure will be described in detail with reference to the accompanying drawings so that those skilled in the art may easily practice the present disclosure. It should be understood that the present disclosure may be embodied in different ways and is not limited to the following embodiments. In order to clearly describe the present disclosure, portions not related to the description will be omitted from the drawings. Like components will be denoted by like reference numerals throughout the specification.

The words and terms used in the present specification and claims should not be construed as being limited to conventional or dictionary meanings and should be interpreted with meanings and concepts consistent with the technical idea of the present disclosure on the basis of the principle that an inventor can properly define the concepts of terms in order to explain his or her disclosure in the best way.

Therefore, the embodiments described in the present specification and the configurations illustrated in the drawings are only exemplary embodiments of the present disclosure and do not represent all the technical ideas of the present disclosure, and thus it should be understood that there may be various equivalents and variations that can replace them at the time of application.

In the following description, descriptions of some components may be omitted to clarify the features of the present disclosure.

### 1. Definitions of Terms

The term “communication” as used in the following description means that one or more members are fluidly connected to fluidly communicate with each other. In one embodiment, communication may be formed by a member such as a conduit, pipe, or tubing.

The term “electrical connection” as used in the following description means that one or more members are connected to each other to be able to transmit current or electrical signals. In one embodiment, the electrical connection may be performed through a wire form such as a conductor member or through a wireless form such as Bluetooth, Wi-Fi, or radio frequency identification (RFID).

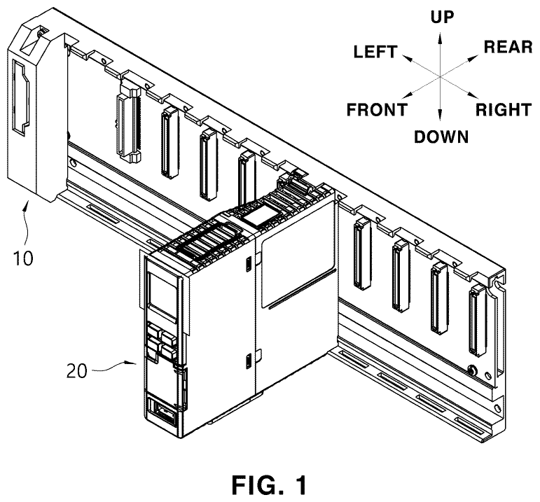

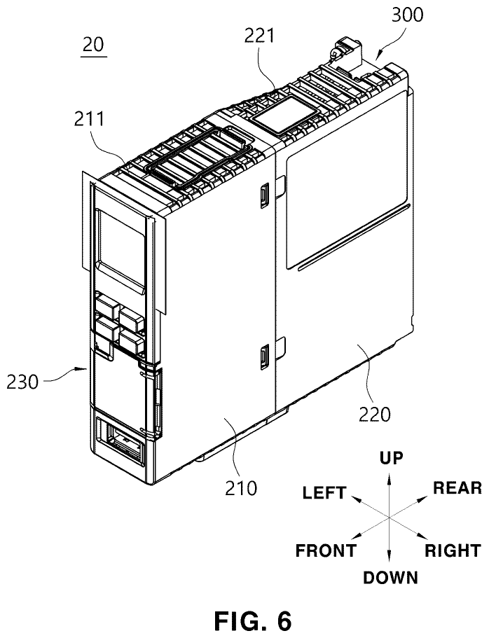

The terms “up,” “down,” “left,” “right,” “front,” and “rear” as used in the following description will be understood with reference to a coordinate system shown in FIGS. 1 and 6.

### 2. Description of a Terminal Member 10 According to an Embodiment of the Present Disclosure

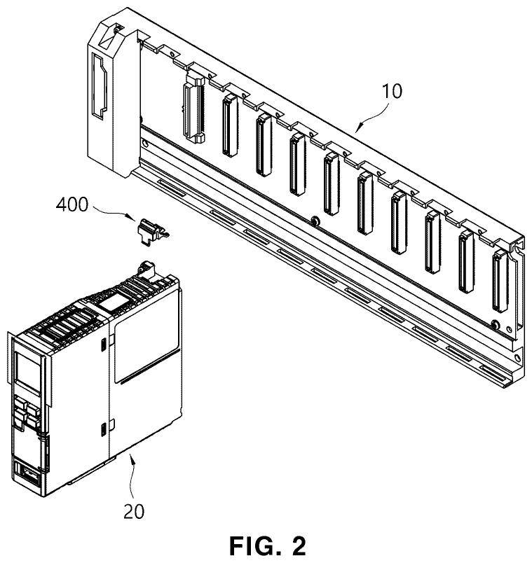

Referring to FIGS. 1 and 2, the terminal member 10 according to the embodiment of the present disclosure is shown.

The terminal member 10 communicates with and is electrically connected to an external power source and an external power load. The terminal member 10 may receive power from the external power source and may transmit power to the external load.

The terminal member 10 communicates with and is electrically connected to a power electronic device 20. The terminal member 10 may transmit received power to the power electronic device 20 and may receive power from the power electronic device 20.

The terminal member 10 is coupled to the power electronic device 20. Specifically, the terminal member 10 is detachably coupled to the power electronic device 20. In one embodiment, the terminal member 10 may be detachably coupled to a plurality of power electronic devices 20.

The terminal member 10 may have any shape that may be electrically connected to, may communicate with, and may be detachably coupled to the external power source, the external load, and the power electronic device 20. In the illustrated embodiment, the terminal member 10 is formed in a quadrangular plate shape that laterally extends and has a vertical height.

In the above embodiment, the power electronic device 20 may be moved rearward and coupled to the terminal member 10 and may be moved forward and separated from the terminal member 10. In this case, the terminal member 10 and the power electronic device 20 may be easily coupled to or separated from each other by a coupling member 400 which will be described in detail below.

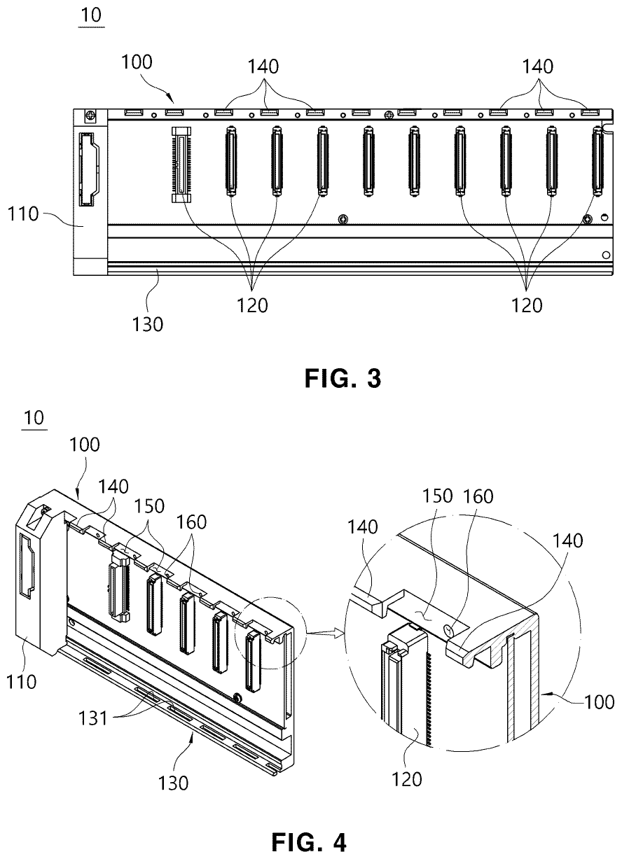

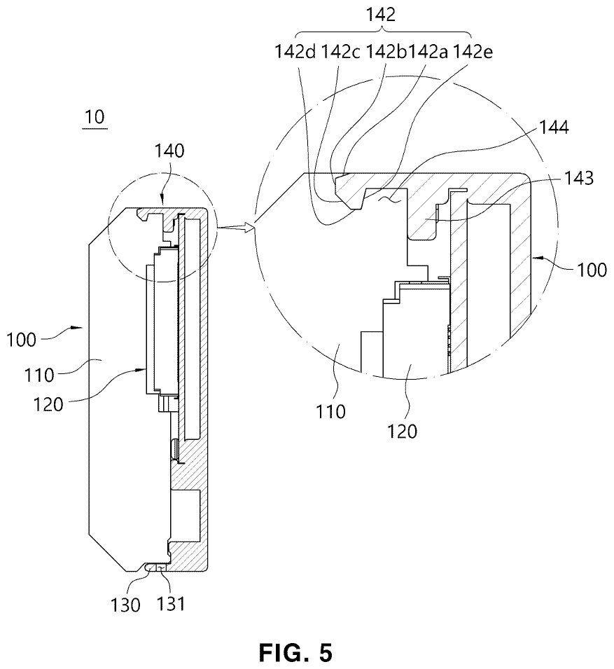

In the embodiment shown in FIGS. 3 to 5, the terminal member 10 includes a terminal body 100.

The terminal body 100 forms a body of the terminal member 10. The terminal body 100 is formed in the same shape as the terminal member 10. In the illustrated embodiment, the terminal body 100 is formed in a quadrangular plate shape that has a lateral length and a vertical height.

In the above embodiment, one side of the terminal body 100 to which the power electronic device 20 is coupled, a front side in the illustrated embodiment, is formed to be open.

In the illustrated embodiment, the terminal body 100 includes a conductive member 110, a slot member 120, a support base 130, a support member 140, a device accommodation portion 150, and a fastening hole 160.

The conductive member 110 is a portion through which the terminal member 10 communicates with and is electrically connected to an external power source and an external load. The conductive member 110 communicates with and is electrically connected to the external power source and the external load in a wired or wireless manner.

The conductive member 110 communicates with and is electrically connected to the slot member 120. As will be described below, a plurality of slot members 120 are provided to be coupled to, communicate with, and be electrically connected to the plurality of power electronic devices 20. The conductive member 110 communicates with and is electrically connected to each of the plurality of slot members 120. Accordingly, it may be regarded that the conductive member 110 communicates with and is electrically connected to the power electronic device 20 through the slot member 120.

The conductive member 110 may be disposed at any position at which the conductive member 110 may communicate with and may be electrically connected to the external power source, the external load, and the slot member 120. In the illustrated embodiment, the conductive member 110 is positioned at one end portion of the terminal body 100 in a length direction, that is, a left end portion thereof.

The conductive member 110 may have any shape that may communicate with and may be electrically connected to the external power source, the external load, and the slot member 120. In the illustrated embodiment, the conductive member 110 is a three-dimensional figure shape having a vertical height, a lateral width, and an anteroposterior thickness.

Although not denoted by a reference symbol, a connector accommodation portion may be provided in the conductive member 110. A connector that communicates with and is electrically connected to the external power source or load may be accommodated in the connector. Accordingly, the external power source or load may be communicated with and may be electrically connected to the conductive member 110.

The slot member 120 is formed at one side of the conductive member 110 facing the power electronic device 20, that is, a front side surface thereof in the illustrated embodiment.

The slot member 120 is a portion through which the terminal body 100 communicates with and is electrically connected to the power electronic device 20. A terminal member 240 of the power electronic device 20 is inserted into the slot member 120 to be withdrawable. Through such coupling, the slot member 120 and the terminal member 240 may communicate with and may be electrically connected to each other so that the terminal member 10 and the power electronic device 20 may communicate with and may be electrically connected to each other.

The slot member 120 may be formed in a shape corresponding to a shape of the terminal member 240. In the illustrated embodiment, the slot member 120 has a quadrangular column shape that is formed to vertically extend and protrudes forward. An opening for accommodating the terminal member 240 is formed to be recessed in a front surface of the slot member 120.

The slot member 120 may be positioned at a position corresponding to a base groove 131 of the support base 130 and the support member 140. In addition, the slot member 120 may be positioned to correspond to a position of the terminal member 240 of the power electronic device 20 coupled to the base groove 131 and the support member 140.

In the illustrated embodiment, the slot member 120 is positioned to overlap the base groove 131 in a height direction thereof, that is, a vertical direction, and is positioned to be biased to the right from the support member 140.

The plurality of slot members 120 may be provided. The plurality of slot members 120 may be disposed apart from each other in a length direction of the terminal body 100. In the illustrated embodiment, ten slot members 120 are provided and disposed to be laterally spaced apart from each other. A separation distance between the slot members 120 may be changed according to a length of a housing 200 of the power electronic device 20 in a width direction, that is, a length thereof in a lateral direction in the illustrated embodiment.

The support base 130 is positioned below the slot member 120.

The support base 130 supports one side of the power electronic device 20, which is coupled to the terminal member 10, in a height direction thereof, that is, a lower side thereof in the illustrated embodiment. The support base 130 partially supports a rear side of a lower portion of the housing 200 of the power electronic device 20.

The support base 130 is positioned at one end portion of the terminal body 100 in a height direction, that is, a lower end portion thereof in the illustrated embodiment. The support base 130 is formed to extend in a direction in which the power electronic device 20 is separated, that is, forward in the illustrated embodiment.

The support base 130 is formed to extend in the same direction as the terminal body 100. In the illustrated embodiment, the support base 130 is formed to extend laterally. One end portion of the support base 130 in an extending direction, a left end portion thereof in the illustrated embodiment, extends to the conductive member 110. The other end portion of the support base 130 in the extending direction, that is, a right end portion thereof in the illustrated embodiment, extends to a right end portion of the terminal body 100.

In the illustrated embodiment, the support base 130 includes the base groove 131.

A protrusion (not shown) formed at the lower portion of the housing 200 of the power electronic device 20 seated on the support base 130 is insertion-coupled to the base groove 131. A lower portion of the power electronic device 20 may be stably fixed by the base groove 131.

The base groove 131 is formed to pass through the interior of the support base 130. The base groove 131 is formed to extend in a thickness direction of the support base 130, that is, a vertical direction thereof in the illustrated embodiment.

The base groove 131 is formed to extend in the same direction as the support base 130. In the illustrated embodiment, the base groove 131 is formed to extend laterally.

The base groove 131 may have any shape into which the protrusion (not shown) provided in the housing 200 of the power electronic device 20 may be insertion-coupled to be withdrawable. In the illustrated embodiment, the base groove 131 is formed to have a vertical height, a rectangular cross section with a lateral length, and an anteroposterior width.

In this case, the anteroposterior width of the base groove 131 may be formed to correspond to a length of an anteroposterior width of the protrusion (not shown).

A plurality of base grooves 131 may be formed. The plurality of base grooves 131 may be disposed apart from each other in the extending direction of the support base 130. In addition, the plurality of base grooves 131 may be disposed to correspond to positions of the slot members 120 and the support members 140.

In the illustrated embodiment, ten base grooves 131 are formed to correspond to the number of slot members 120 and are disposed to be laterally spaced apart from each other. Each base groove 131 is disposed to overlap the slot member 120 and the support member 140 in a height direction thereof, that is, in a vertical direction thereof in the illustrated embodiment.

The base groove 131 may be formed in any shape into which the protrusions (not shown) provided in the housings 200 of the plurality of power electronic devices 20 may be inserted.

For example, one base groove 131 may be formed to extend between end portions of the support base 130 in the extending direction, a left end portion and a right end portion thereof in the illustrated embodiment. In the above embodiment, the protrusions (not shown) provided in the housings 200 of the plurality of power electronic devices 20 may each be inserted into the one base groove 131.

Alternatively, the plurality of base grooves 131 may be provided, and an extension length of each base groove 131 may be formed to be greater than a length of the housing 200 in a width direction, that is, a length thereof in a lateral direction in the illustrated embodiment. In the above embodiment, the protrusions (not shown) provided in the housing 200 of the plurality of power electronic devices 20 may each be inserted into one of the plurality of base grooves 131. That is, the number of base grooves 131 may be smaller than the number of power electronic devices 20 so that the plurality of base grooves 131 may support the plurality of power electronic devices 20.

The support base 130 faces the support member 140 with the slot member 120 interposed therebetween.

The support member 140 supports the other side of the power electronic device 20, which is coupled to the terminal member 10, in the height direction thereof, that is, an upper side thereof in the illustrated embodiment. The support member 140 is coupled to the coupling member 400 coupled to a coupling member attachment-detachment portion 300 of the power electronic device 20 to partially support a rear side of an upper portion of the power electronic device 20.

The support member 140 is positioned at the other end portion of the terminal body 100 in the height direction, that is, an upper end portion thereof in the illustrated embodiment. The support member 140 is formed to protrude in a direction in which the power electronic device 20 is separated, that is, forward in the illustrated embodiment.

The support member 140 is detachably connected to the coupling member 400 provided in the power electronic device 20. In one embodiment, the support member 140 may be hook-fitted to the coupling member 400.

Accordingly, a coupling state between the support member 140 and the coupling member 400 may be maintained unless a predetermined force is applied in a preset direction.

The support member 140 may be disposed at any position at which the support member 140 may be coupled to the coupling member 400 of the power electronic device 20. In the illustrated embodiment, the support member 140 is disposed to overlap the slot member 120 and the base groove 131 in the height direction of the terminal body 100, that is, a vertical direction.

A plurality of support members 140 may be provided. The plurality of support members 140 may be disposed apart from each other in the length direction of the terminal body 100. In the illustrated embodiment, ten support members 140 are provided and disposed to be laterally spaced apart from each other.

In the illustrated embodiment, the support member 140 includes a first extension arm 141, a second extension arm 142, a third extension arm 143, and a member accommodation portion 144.

The first extension arm 141 forms a portion of the support member 140. The first extension arm 141 is formed to extend outward, that is, forward in the illustrated embodiment, from the upper end portion of the terminal body 100. The first extension arm 141 forms an upper portion of the support member 140.

The first extension arm 141 partially covers the coupling member 400 and the coupling member attachment-detachment portion 300, to which the coupling member 400 is coupled, at an upper side. As will be described below, the first extension arm 141 covers a portion of a second coupling body 412 of the coupling member 400 at an upper side.

Among end portions of the first extension arm 141 in an extending direction, one end portion of the first extension arm 141 connected to the terminal body 100, that is, a rear end portion thereof in the illustrated embodiment, is continuous with the upper end portion of the terminal body 100. Among the end portions of the first extension arm 141 in the extending direction, the other end portion of the first extension arm 141 facing the power electronic device 20, that is, a front end portion thereof in the illustrated embodiment, is continuous with the second extension arm 142.

The second extension arm 142 is detachably connected to a coupling protrusion 416 formed at an end portion of a second coupling body 412. In one embodiment, the second extension arm 142 may be hook-fitted to the coupling protrusion 416.

At the same time, the second extension arm 142 presses an upper surface of the second coupling body 412. Accordingly, the coupling member 400 and the support member 140 may be detachably coupled, and a coupling state therebetween can be stably maintained.

The second extension arm 142 is continuous with the first extension arm 141. The second extension arm 142 is continuous with the other end portion of the first extension arm 141, that is, the front end portion thereof in the illustrated embodiment.

The second extension arm 142 may be divided into a plurality of portions. In the illustrated embodiment, the second extension arm 142 includes a first extension surface 142a, a second extension surface 142b, a third extension surface 142c, a fourth extension surface 142d, and a fifth extension surface 142e.

The first extension surface 142a is a portion that is continuous with the first extension arm 141 among portions of the second extension arm 142. The first extension surface 142a extends to form a predetermined angle with the first extension arm 141. In the illustrated embodiment, the first extension surface 142a extends downwardly forward to form an obtuse angle with the first extension arm 141. In other words, the first extension surface 142a obliquely extends downwardly forward and upwardly rearward.

The second extension surface 142b is continuous with the first extension surface 142a to form a predetermined angle therewith. In the illustrated embodiment, the second extension surface 142b extends toward the coupling member 400, that is, downward, to form an obtuse angle with the first extension surface 142a. In other words, the second extension surface 142b extends vertically and obliquely.

The third extension surface 142c is continuous with the second extension surface 142b to form a predetermined angle therewith. In the illustrated embodiment, the third extension surface 142c extends toward the coupling member 400, that is, downwardly rearward, to form an obtuse angle with the second extension surface 142b. In other words, the third extension surface 142c obliquely extends upwardly forward and downwardly rearward.

When the power electronic device 20 moves toward the terminal member 10, the third extension surface 142c comes into contact with the coupling protrusion 416 of the coupling member 400. In this case, a second support surface 416b of the coupling protrusion 416 obliquely extends to correspond to the third extension surface 142c. Therefore, the coupling member 400 may be easily inserted into and coupled to the support member 140.

The fourth extension surface 142d is continuous with the third extension surface 142c to form a predetermined angle therewith. In the illustrated embodiment, the fourth extension surface 142d extends toward the terminal body 100, that is, rearward in the illustrated embodiment, to form an obtuse angle with the third extension surface 142c. In other words, the fourth extension surface 142d obliquely extends in an anteroposterior direction.

When the coupling member 400 is coupled to the support member 140, the upper surface of the second coupling body 412 of a coupling body 410 may come into contact with the fourth extension surface 142d. Accordingly, a coupling state of the coupling member 400 coupled to the terminal member 10 can be stably maintained.

The fifth extension surface 142e is continuous with the fourth extension surface 142d to form a predetermined angle therewith. In the illustrated embodiment, the fifth extension surface 142e extends toward the first extension arm 141, that is, upwardly rearward, to form an obtuse angle with the fourth extension surface 142d. In other words, the fifth extension surface 142e obliquely extends downwardly forward and upwardly rearward.

When the coupling member 400 is coupled to the support member 140, the fifth extension surface 142e comes into contact with the coupling protrusion 416 of the coupling body 410. In this case, a first support surface 416a of the coupling protrusion 416 may obliquely extend to correspond to the fifth extension surface 142e. Accordingly, the coupling protrusion 416 may be stably supported by the fifth extension surface 142e so that a coupling state of the coupling member 400 coupled to the terminal member 10 can be stably maintained.

The third extension arm 143 reinforces the rigidity of the first extension arm 141. In addition, the third extension arm 143 limits a length by which the coupling member 400 is inserted into the support member 140.

The third extension arm 143 is continuous with the first extension arm 141 to form a predetermined angle therewith. In the illustrated embodiment, the third extension arm 143 is formed to vertically extend perpendicular to the first extension arm 141.

The third extension arm 143 is positioned apart from the second extension arm 142. In the illustrated embodiment, the third extension arm 143 is positioned adjacent to the terminal body 100 at a rear side of the first extension arm 141.

A space formed by being surrounded by the first extension arm 141, the second extension arm 142, and the third extension arm 143 is defined as the member accommodation portion 144.

The member accommodation portion 144 is a space for accommodating the coupling member 400. The member accommodation portion 144 is defined by being partially surrounded by the first extension arm 141, the second extension arm 142, and the third extension arm 143. One side of the member accommodation portion 144 facing the power electronic device 20, that is, a front side thereof in the illustrated embodiment, is formed to be open. The coupling member 400 may be inserted into or withdrawn from the member accommodation portion 144 through the one side.

The member accommodation portion 144 may be formed to have a height greater than a height of the coupling member 400, that is, a length thereof in a vertical direction. In addition, the member accommodation portion 144 may be formed to have a length that is greater than a length of the coupling member 400, that is, a length thereof in an anteroposterior direction. Accordingly, when the power electronic device 20 coupled to the terminal member 10 vibrates, shock caused by the vibration may be buffered by the coupling member 400.

The device accommodation portion 150 is a space for accommodating a portion of the housing 200 of the power electronic device 20. In the illustrated embodiment, the device accommodation portion 150 accommodates left and right portions of the coupling member attachment-detachment portion 300 formed at an upper side of a rear portion of a second housing 220.

The device accommodation portion 150 may be formed to correspond to a shape of a remaining portion of the upper side of the rear portion of the second housing 220 excluding the coupling member attachment-detachment portion 300. In the illustrated embodiment, the device accommodation portion 150 is formed to extend laterally like the terminal body 100.

One side of the device accommodation portion 150 facing the power electronic device 20, that is, a front side thereof in the illustrated embodiment, is formed to be open. The second housing 220 may be inserted into or withdrawn from the device accommodation portion 150 through the one side.

Among other sides of the device accommodation portion 150, respective sides thereof in a height direction, that is, an upper side and a lower side thereof in the illustrated embodiment, are formed to be open. When the terminal member 10 or the power electronic device 20 coupled thereto vibrates vertically, the power electronic device 20 vibrates through the respective sides of the device accommodation portion 150, and shock can be mitigated.

A plurality of device accommodation portions 150 may be formed. The plurality of device accommodation portions 150 may be disposed apart from each other. In the illustrated embodiment, ten device accommodation portions 150 are provided and disposed apart from each other in an extending direction of the terminal body 100, that is, a lateral direction.

The plurality of support members 140 are positioned between the plurality of device accommodation portions 150. In other words, the plurality of support members 140 and the plurality of device accommodation portions 150 are alternately disposed in the length direction of the terminal body 100.

The fastening hole 160 is formed inside the device accommodation portion 150.

The fastening hole 160 is a space into which a fastening member 260 of the housing 200 is inserted. The fastening hole 160 is formed to be recessed in one surface of the terminal body 100 surrounding the device accommodation portion 150, that is, a front surface thereof in the illustrated embodiment.

The fastening hole 160 may be positioned to correspond to a position of the fastening member 260. In the illustrated embodiment, the fastening hole 160 is positioned inside the device accommodation portion 150 to be biased to the right.

The fastening hole 160 may be formed in any shape to which the fastening member 260 may be insertion-coupled. In an embodiment in which the fastening member 260 is provided as a screw member, the fastening hole 160 may have screw threads formed on an inner circumferential surface thereof.

Through coupling between the fastening hole 160 and the fastening member 260, the upper portion of the power electronic device 20 may be coupled to the terminal member 10 by a plurality of members, that is, the coupling member 400 and the fastening member 260. Accordingly, a coupling state between the terminal member 10 and the power electronic device 20 can be stably maintained.

A plurality of fastening holes 160 may be formed. The plurality of fastening holes 160 may each be formed in one of the plurality of device accommodation portions 150. In the illustrated embodiment, ten fastening holes 160 are formed and each is disposed in one of ten device accommodation portions 150.

### 3. Description of the Power Electronic Device 20 According to the Embodiment of the Present Disclosure

Referring again to FIGS. 1 and 2, the power electronic device 20 according to the embodiment of the present disclosure is shown.

The power electronic device 20 may be provided in any form capable of accommodating various electrical and electronic devices therein to perform preset functions. In one embodiment, the power electronic device 20 may include a programmable logic controller (PLC) and may be configured to control or monitor the operations of other electrical devices that are electrically connected. In the above embodiment, the power electronic device 20 may be electrically connected to another external device.

The power electronic device 20 is detachably connected to the terminal member 10. A portion of the coupling may be achieved by the coupling member 400, which will be described in detail below.

The power electronic device 20 coupled to the terminal member 10 may communicate with and may be electrically connected to the terminal member 10. Accordingly, the power electronic device 20 may communicate with and may be electrically connected to each of an external power source and an external load.

The plurality of power electronic devices 20 may be provided. The plurality of power electronic devices 20 may communicate with and may be electrically connected to each other. In the above embodiment, the number of the power electronic devices 20 which communicate with and are electrically connected to each other may be adjusted so that the capacity of an entire electrical device including the power electronic devices 20 may be adjusted.

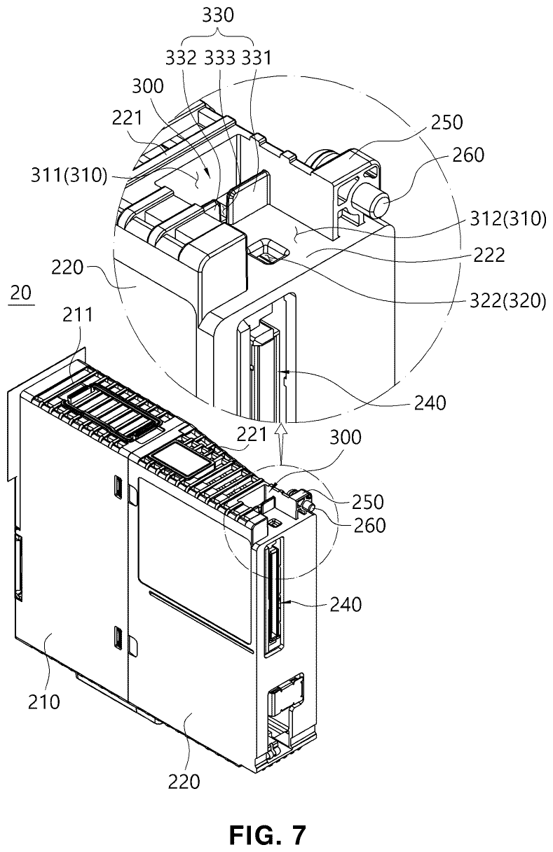

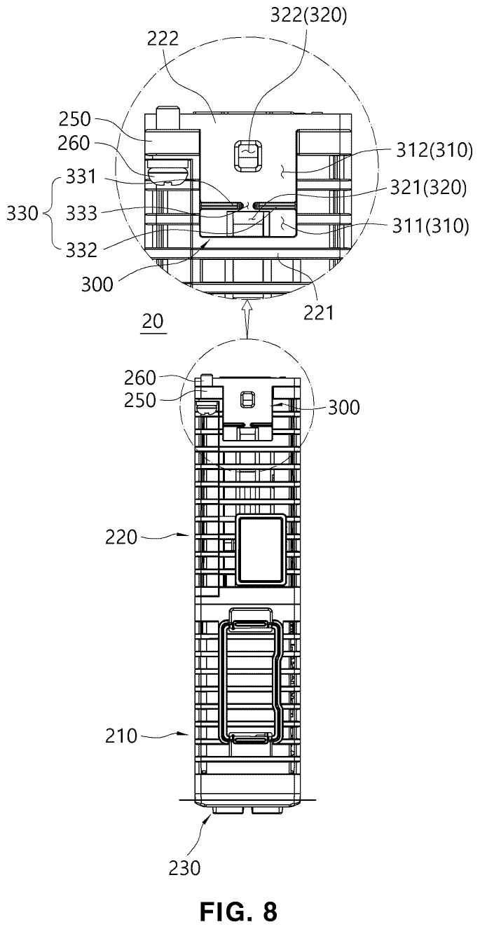

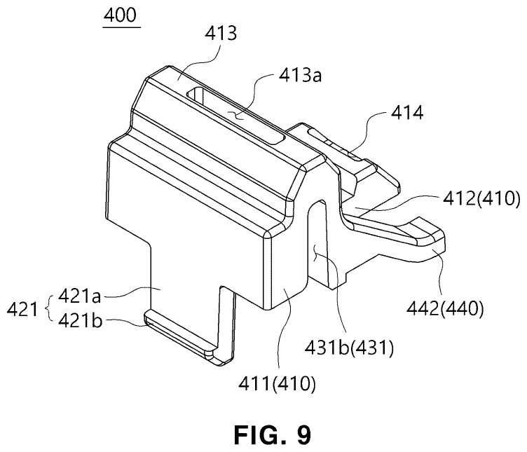

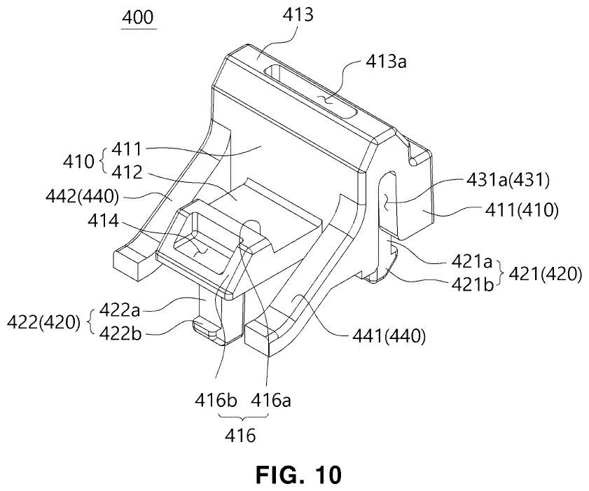

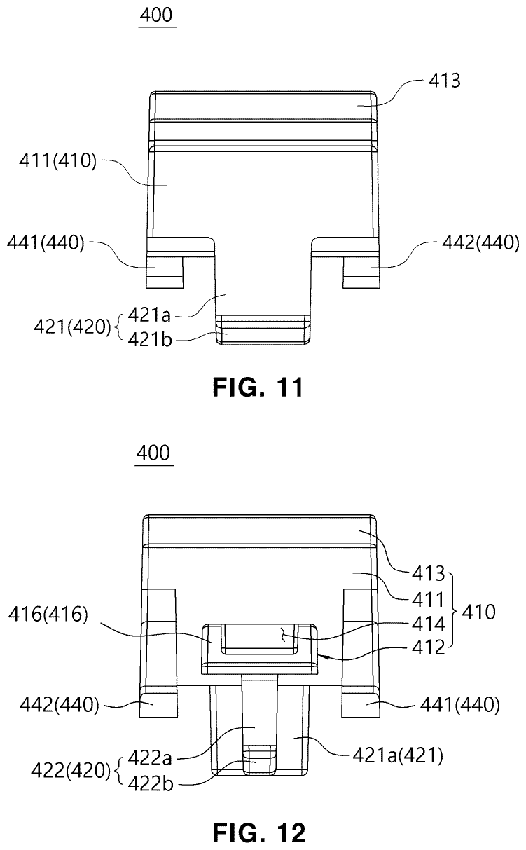

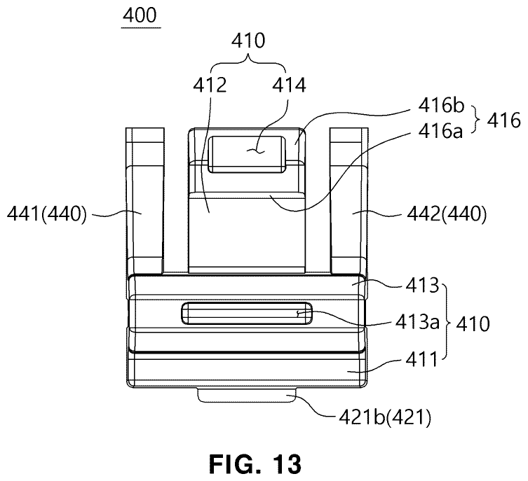

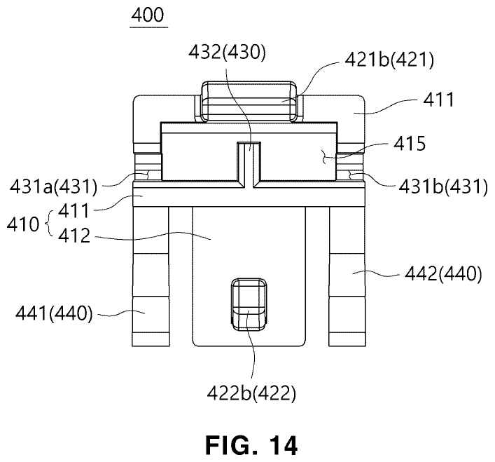

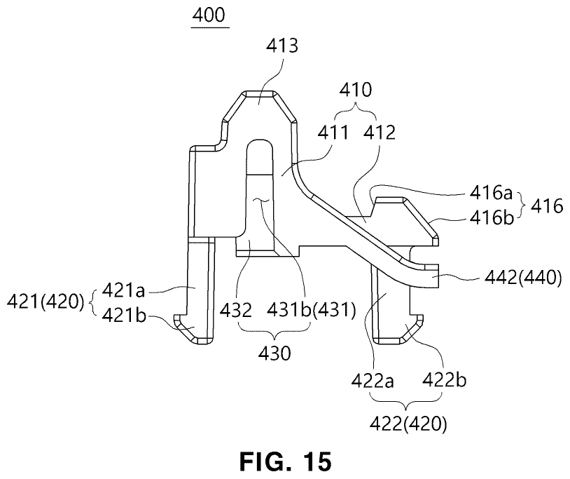

Referring to FIGS. 6 to 8, the power electronic device 20 according to the illustrated embodiment includes the housing 200 and the coupling member attachment-detachment portion 300. In addition, the power electronic device 20 further includes the coupling member 400 illustrated in FIGS. 9 to 15, and the coupling member 400 is described separately.

The housing 200 forms an exterior of the power electronic device 20. The housing 200 is a portion through which the power electronic device 20 is exposed to the outside. In addition, the housing 200 is a portion through which the power electronic device 20 is connected to the terminal member 10.

A space is formed inside the housing 200. Any components of the power electronic devices 20 for performing preset functions, such as a printed circuit board (PCB) and a capacitor, may be accommodated in the space. The space of the housing 200 communicates with and is electrically connected to the terminal member 10.

In the illustrated embodiment, the housing 200 includes a first housing 210, the second housing 220, a manipulation portion 230, the terminal member 240, a fastening support portion 250, and the fastening member 260.

The first housing 210 forms a portion of the housing 200. In the illustrated embodiment, the first housing 210 forms a front side of the housing 200.

The first housing 210 is coupled to the second housing 220. In one embodiment, the first housing 210 may be detachably coupled to the second housing 220. In the above embodiment, the first housing 210 and the second housing 220 may be easily separated so that maintenance of the power electronic device 20 may be facilitated.

A space for accommodating any components is formed inside the first housing 210. The first housing 210 may have any shape that may accommodate each component of the power electronic device 20 and may be coupled to the second housing 220. In the illustrated embodiment, the first housing 210 has a quadrangular column shape in which an anteroposterior extension length is greater than a lateral extension length and which has a height in a vertical direction.

In this case, among respective sides of the first housing 210, one side thereof facing the second housing 220, that is, a rear side thereof in the illustrated embodiment, may be open so that an internal space of the first housing 210 may communicate with an internal space of the second housing 220.

In the illustrated embodiment, the first housing 210 includes a first frame 211.

The first frame 211 is formed to extend along an outer surface of the first housing 210. The first frame 211 may function as a reinforcing rib that reinforces the rigidity of the first housing 210. In addition, the first frame 211 may function as a fin that discharges heat generated in any components accommodated inside the first housing 210.

A plurality of first frames 211 may be formed. The plurality of first frames 211 may be disposed apart from each other in a length direction of the first housing 210. In the illustrated embodiment, the plurality of first frames 211 are disposed on an upper surface of the first housing 210 to be spaced apart from each other in an anteroposterior direction.

The second housing 220 forms another portion of the housing 200. In the illustrated embodiment, the second housing 220 forms a rear side of the housing 200.

The second housing 220 is a portion through which the power electronic device 20 is connected to the terminal member 10. In the illustrated embodiment, upper and lower sides of a rear side of the second housing 220 are coupled to the terminal member 10. In addition, the terminal member 240 disposed on one surface of the second housing 220 facing the terminal member 10 among surfaces of the second housing 220, that is, a rear surface thereof in the illustrated embodiment, is connected to the slot member 120 to communicate with and be electrically connected to the slot member 120.

The coupling member attachment-detachment portion 300 is formed at one side of the second housing 220 facing the terminal member 10 among portions of the second housing 220, that is, a rear upper side thereof in the illustrated embodiment, and thus the coupling member 400 is detachably coupled.

The second housing 220 is coupled to the first housing 210. In one embodiment, the second housing 220 may be detachably coupled to the first housing 210.

A space for accommodating any components is formed inside the second housing 220. The second housing 220 may have any shape that may accommodate each component of the power electronic device 20 and may be coupled to the first housing 210. In the illustrated embodiment, the second housing 212 has a quadrangular column shape in which an anteroposterior extension length is greater than a lateral extension length and which has a height in a vertical direction.

In this case, among respective sides of the second housing 220, the other side thereof facing the first housing 210, that is, a front side thereof in the illustrated embodiment, may be open so that the internal space of the second housing 220 may communicate with the internal space of the first housing 210.

In the illustrated embodiment, the second housing 220 includes a second frame 221 and an upper surface 222.

The second frame 221 is formed to extend along an outer surface of the second housing 220. The second frame 221 may function as a reinforcing rib that reinforces the rigidity of the second housing 220. In addition, the second frame 221 may function as a fin that discharges heat generated in any components accommodated inside the second housing 220.

A plurality of second frames 221 may be formed. The plurality of second frames 221 may be disposed apart from each other in a length direction of the second housing 220. In the illustrated embodiment, the plurality of second frames 221 are disposed on an upper surface of the second housing 220 to be spaced apart from each other in an anteroposterior direction.

The upper surface 222 forms a portion of one surface of the second housing 220 facing the coupling member 400a, that is, a portion of the upper surface thereof in the illustrated embodiment. In the illustrated embodiment, the upper surface 222 is formed by a rear side of the upper surface of the second housing 220 being positioned to be biased. The upper surface 222 is partially surrounded by the second frame 221.

The coupling member attachment-detachment portion 300 is formed on the upper surface 222. In addition, the upper surface 222 supports the coupling member 400 coupled to the coupling member attachment-detachment portion 300.

The manipulation portion 230 receives a control signal for controlling the operation of the power electronic device 20. The manipulation portion 230 is positioned at the other side of the first housing 210 opposite the second housing 220 among respective sides of the first housing 210, that is, a front side thereof in the illustrated embodiment. Therefore, a worker may easily access the manipulation portion 230 to apply a control signal.

The manipulation portion 230 communicates with and is electrically connected to the terminal member 240 and any components accommodated in the internal space of the first housing 210 or the second housing 220.

The manipulation portion 230 may be provided in any form capable of receiving a control signal. In the illustrated embodiment, the manipulation portion 230 is provided to include a plurality of buttons and a screen.

The terminal member 240 is a portion through which the power electronic device 20 communicates with and is electrically connected to the terminal member 10. The terminal member 240 is insertion-coupled to the slot member 120 to be withdrawable. Through the coupling, the terminal member 240 and the slot member 120 may communicate with and may be electrically connected to each other.

The terminal member 240 is disposed at the one side of the second housing 220 facing the terminal member 10 among the respective sides of the second housing 220, that is, a rear side thereof in the illustrated embodiment. The terminal member 240 is exposed to the outside of the second housing 220.

The terminal member 240 may be formed to correspond to a shape of the slot member 120. In the illustrated embodiment, the terminal member 240 is formed to extend in a height direction of the second housing 220, that is, a vertical direction.

The fastening support portion 250 is a portion through which the fastening member 260 is coupled to the second housing 220. The fastening support portion 250 is continuous with the second frame 221 and disposed to partially surround the upper surface 222. In the illustrated embodiment, the fastening support portion 250 is positioned at a left side of the upper surface 222. A position of the fastening support portion 250 may be changed according to a position of the fastening hole 160.

The fastening support portion 250 may have any shape that may be coupled to the fastening member 260. In the illustrated embodiment, the fastening support portion 250 is formed to have a width in a lateral direction and a thickness in an anteroposterior direction.

A space is formed to pass through the interior of the fastening support portion 250 in a thickness direction thereof, that is, an anteroposterior direction thereof, and thus the fastening member 260 may may pass through and be coupled to the space. In an embodiment in which the fastening member 260 is provided as a screw member, screw threads may be formed on an inner circumferential surface surrounding the space.

The fastening member 260 connects the second housing 220 and the terminal member 10. As described above, since the second housing 220 and the terminal member 10 are coupled by the coupling member 400, it may be regarded that the fastening member 260 may additionally couple the second housing 220 and the terminal member 10. Coupling between the second housing 220 and the terminal member 10 can be stably maintained by the fastening member 260.

The fastening member 260 is coupled to the fastening support portion 250 and the fastening hole 160. Specifically, the fastening member 260 passes through the space formed in the fastening support portion 250 and is insertion-coupled to the fastening hole 160. In one embodiment, the fastening member 260 may be screw-coupled to each of the fastening support portion 250 and the fastening hole 160.

The coupling member attachment-detachment portion 300 is a portion through which the coupling member 400 is coupled to the housing 200, specifically, the second housing 220. The coupling member attachment-detachment portion 300 is formed at the one side of the second housing 220, that is, a rear upper side thereof in the illustrated embodiment.

The coupling member attachment-detachment portion 300 is partially surrounded by the second frame 221 and the upper surface 222. In the illustrated embodiment, among respective sides of the coupling member attachment-detachment portion 300, a front side, a left side, and a right side thereof are surrounded by the second frame 221, and a lower side thereof is surrounded by the upper surface 222. Among the respective sides of the coupling member attachment-detachment portion 300, the remaining sides thereof, that is, an upper side and a rear side thereof in the illustrated embodiment, are formed to be open.

The coupling member 400 may be coupled to or separated from the coupling member attachment-detachment portion 300 through an upper side. In addition, the power electronic device 20 may be coupled to or separated from the terminal member 10 through a rear side. In one embodiment, the coupling member attachment-detachment portion 300 may be formed integrally with the second housing 220.

In the illustrated embodiment, the coupling member attachment-detachment portion 300 includes a coupling member accommodation portion 310, a coupling opening 320, and a member guide portion 330.

The coupling member accommodation portion 310 is a space for accommodating the coupling member 400. In addition, the coupling member accommodation portion 310 accommodates other components of the coupling member attachment-detachment portion 300. The coupling member accommodation portion 310 is defined by being partially surrounded by the second frame 221 and the upper surface 222.

The coupling member accommodation portion 310 may be divided into a plurality of portions by the member guide portion 330. In the illustrated embodiment, the coupling member accommodation portion 310 includes a first coupling member accommodation portion 311 formed at a front side and a second coupling member accommodation portion 312 formed at a rear side.

The first coupling member accommodation portion 311 accommodates a portion of a first coupling body 411 of the coupling member 400. The first coupling member accommodation portion 311 is defined by being surrounded by the second frame 221, the upper surface 222, and guide plates 331 and 332. An upper side of the first coupling member accommodation portion 311 is formed to be open.

The first coupling member accommodation portion 311 communicates with a space formed inside the second housing 220. Specifically, the first coupling member accommodation portion 311 and the space communicate with each other by a first coupling opening 321 formed to pass through a portion of the upper surface 222 surrounding the first coupling member accommodation portion 311.

The second coupling member accommodation portion 312 accommodates another portion of the first coupling body 411 of the coupling member 400, the second coupling body 412, and a support arm 440. The second coupling member accommodation portion 312 is defined by being surrounded by the second frame 221, the upper surface 222, and the guide plates 331 and 332. An upper side and a rear side of the second coupling member accommodation portion 312 are formed to be open.

The second coupling member accommodation portion 312 communicates with a space formed inside the second housing 220. Specifically, the second coupling member accommodation portion 312 and the space communicate with each other by a second coupling opening 322 formed to pass through another portion of the upper surface 222 surrounding the second coupling member accommodation portion 312.

The second coupling member accommodation portion 312 may be formed to have a relatively larger volume than the first coupling member accommodation portion 311. As will be described below, this is because a volume of the other portion of the first coupling body 411, the second coupling body 412, and the support arm 440 accommodated in the second coupling member accommodation portion 312 is greater than a volume of the one portion of the first coupling body 411 accommodated in the first coupling member accommodation portion 311.

The coupling opening 320 is formed to pass through the upper surface 222 to allow the coupling member accommodation portion 310 and an internal space of the second housing 220 to communicate with each other. A coupling arm 420 of the coupling member 400 may pass through the coupling opening 320 to be partially accommodated in the internal space of the second housing 220.

A plurality of coupling openings 320 may be formed. The plurality of coupling openings 320 may each be formed in one of a plurality of coupling member accommodation portions 310. In the illustrated embodiment, the coupling opening 320 includes the first coupling opening 321 formed in the first coupling member accommodation portion 311 and the second coupling opening 322 formed in the second coupling member accommodation portion 312.

A first coupling arm 421 passes through and is withdrawably coupled to the first coupling opening 321. A second coupling arm 422 passes through and is withdrawably coupled the second coupling opening 322. Through the coupling, the coupling arm 420 may be hook-fitted to the second housing 220.

In the illustrated embodiment, the first coupling opening 321 and the second coupling opening 322 are formed to have a quadrangular cross section. Shapes of the first coupling opening 321 and the second coupling opening 322 may be changed according to shapes of the first coupling arm 421 and the second coupling arm 422.

The member guide portion 330 guides the coupling member 400 such that the coupling member 400 is coupled to the coupling member attachment-detachment portion 300 in a preset direction at a preset position.

The member guide portion 330 is positioned in the coupling member accommodation portion 310. The member guide portion 330 divides the coupling member accommodation portion 310 into a plurality of portions. In the illustrated embodiment, the member guide portion 330 is positioned to be biased toward a front side of the coupling member accommodation portion 310, thereby dividing the coupling member accommodation portion 310 into the first coupling member accommodation portion 311 and the second coupling member accommodation portion 312.

The member guide portion 330 and the coupling member 400 may be coupled in a form in which one is movably inserted into the other. In this case, the member guide portion 330 and the coupling member 400 may be inserted into and movably coupled to each other at a plurality of positions.

In the illustrated embodiment, the member guide portion 330 includes a first guide plate 331, a second guide plate 332, and a rib accommodation portion 333.

The first guide plate 331 and the second guide plate 332 are formed to protrude from the upper surface 222. In the illustrated embodiment, the first guide plate 331 and the second guide plate 332 are formed to protrude upward.

The first guide plate 331 is insertion-coupled to a first guide groove 431a of the coupling member 400. The first guide plate 331 extends in an extending direction of the first guide groove 431a, that is, a vertical direction in the illustrated embodiment. The first guide plate 331 may be movably inserted into the first guide groove 431a such that the lifting and lowering of the coupling member 400 may be guided.

The second guide plate 332 is insertion-coupled to a second guide groove 431b of the coupling member 400. The second guide plate 332 extends in an extending direction of the second guide groove 431b, that is, a vertical direction in the illustrated embodiment. The second guide plate 332 may be movably inserted into the second guide groove 431b so that the lifting and lowering of the coupling member 400 may be guided.

The first guide plate 331 and the second guide plate 332 are formed to extend in a width direction of the second housing 220, that is, a lateral direction in the illustrated embodiment. In this case, an extension length of each of the first guide plate 331 and the second guide plate 332 may be formed to be less than half of a length of the coupling member accommodation portion 310 in a width direction.

Accordingly, the first guide plate 331 and the second guide plate 332 are disposed in parallel with a predetermined space formed therebetween. In the illustrated embodiment, the first guide plate 331 is positioned to be biased to the left, and the second guide plate 332 is positioned to biased to the right. Accordingly, a left side and a right side of the coupling member 400 may both be guided, and the coupling member 400 may be lifted or lowered to be coupled to the coupling member attachment-detachment portion 300 or separated from the coupling member attachment-detachment portion 300.

The predetermined space formed between the first guide plate 331 and the second guide plate 332 is defined as the rib accommodation portion 333.

The rib accommodation portion 333 is a space for accommodating a guide rib 432 of the coupling member 400. The guide rib 432 may be inserted into the rib accommodation portion 333 to be withdrawable.

The rib accommodation portion 333 is positioned between the first guide plate 331 and the second guide plate 332. A left side and a right side of the guide rib 432 accommodated in the rib accommodation portion 333 may be restrained by the first guide plate 331 and the second guide plate 332.

Accordingly, the coupling member 400 coupled to the coupling member attachment-detachment portion 300 is allowed to move in a vertical direction and is restricted from moving in an anteroposterior or lateral direction. Accordingly, a coupling state between the coupling member 400 and the coupling member attachment-detachment portion 300 can be stably maintained.

It will be understood that positions and shapes of the first guide plate 331, the second guide plate 332, and the rib accommodation portion 333 described above may be changed according to a position and a shape of a guide portion 430 of the coupling member 400.

### 4. Description of the Coupling Member 400 According to the Embodiment of the Present Disclosure

Referring again to FIG. 2, the power electronic device 20 according to the embodiment of the present disclosure includes the coupling member 400.

The coupling member 400 is detachably coupled to each of the coupling member attachment-detachment portion 300 and the terminal member 10. In other words, the coupling member 400 detachably couples the power electronic device 20 and the terminal member 10.

In the description of the present specification, it has been assumed that the coupling member 400 is a component of the power electronic device 20. Alternatively, the coupling member 400 may be provided separately from the power electronic device 20.

In the illustrated embodiment, one coupling member 400 is provided. Alternatively, a plurality of coupling members 400 may each be provided and detachably coupled to one of the coupling member attachment-detachment portions 300 and the terminal member 10 at a plurality of positions. In the above embodiment, it will be understood that a plurality of coupling member attachment-detachment portions 300 are also provided.

In one embodiment, the coupling member 400 may be hook-fitted to each of the coupling member attachment-detachment portion 300 and the support member 140. Accordingly, the coupling member 400 may be easily coupled to the coupling member attachment-detachment portion 300 and the support member 140, and a coupling state thereof can be stably maintained.

In addition, the coupling member 400 according to the embodiment of the present disclosure may buffer vertical vibrations of the power electronic device 20 by its own structure without having a separate elastic member. Therefore, manufacturing costs can be reduced, manufacturing efficiency can be improved, and maintenance can be easily performed.

Components of the coupling member 400 to be described below may be formed integrally. Therefore, the number of processes of separately manufacturing components to couple the components can be reduced, and coupling between the components can be firmly maintained.

In one embodiment, among the components of the coupling member 400 to be described below, the coupling arm 420 may be made of polycarbonate glass fiber 10% (PC GF 10%). In addition, other components of the coupling member 400 may be made of polycarbonate/acrylonitrile butadiene styrene (PC-ABS).

In the above embodiment, the coupling arm 420 may have increased strength and tensile strength as compared to other components of the coupling member 400.

In the embodiments illustrated in FIGS. 9 to 15, the coupling member 400 includes the coupling body 410, the coupling arm 420, the guide portion 430, and the support arm 440.

The coupling body 410 forms a body of the coupling member 400. The coupling body 410 is a portion of the coupling member 400 accommodated in the coupling member attachment-detachment portion 300. The coupling body 410 is continuous with some components of the coupling member 400. In addition, other components of the coupling member 400 are formed in the coupling body 410.

In the illustrated embodiment, the coupling body 410 includes the first coupling body 411, the second coupling body 412, a pressing protrusion 413, a pressing groove 414, a plate accommodation groove 415, and the coupling protrusion 416.

The first coupling body 411 forms a portion of the coupling body 410, that is, a front side thereof in the illustrated embodiment. The first coupling body 411 is partially accommodated in each of the first coupling member accommodation portion 311 and the second coupling member accommodation portion 312.

The first coupling body 411 is formed to extend in a direction in which the coupling member 400 is coupled to or separated from the coupling member attachment-detachment portion 300, that is, a vertical direction in the illustrated embodiment.

The first coupling body 411 may have any shape that may be accommodated in the coupling member accommodation portion 310 and coupled to the member guide portion 330. In the illustrated embodiment, the first coupling body 411 has a polygonal column shape having a height in a vertical direction and a width in a lateral direction.

The first coupling body 411 may be divided into a plurality of portions. In the illustrated embodiment, the first coupling body 411 includes a first portion which forms a portion of a front side and is accommodated in the first coupling member accommodation portion 311 and a second portion which forms a portion of a rear side and is accommodated in the second coupling member accommodation portion 312.

A guide groove 431 of the guide portion 430 is positioned between the first portion and the second portion. In other words, the first coupling body 411 is divided into the first portion and the second portion by the guide groove 431 positioned therein.

Accordingly, the first portion and the second portion are positioned to face each other with the guide plates 331 and 332, which are inserted into the guide groove 431, interposed therebetween.

One side of the first portion of the first coupling body 411, that is, a lower side thereof in the illustrated embodiment, is continuous with the first coupling arm 421 of the coupling arm 420. The other side of the first coupling body 411, that is, an upper side thereof in the illustrated embodiment, is continuous with the pressing protrusion 413. The other side of the second portion of the first coupling body 411, that is, a rear side thereof in the illustrated embodiment, is continuous with the second coupling body 412.

Furthermore, the other side of the second portion of the first coupling body 411, that is, the rear side thereof in the illustrated embodiment, is continuous with the support arm 440.

The second coupling body 412 forms another portion of the coupling body 410, that is, a rear side thereof in the illustrated embodiment. The second coupling body 412 is accommodated in the second coupling member accommodation portion 312.

The second coupling body 412 is formed to extend in the direction in which the coupling member 400 is coupled to or separated from the support member 140, that is, an anteroposterior direction in the illustrated embodiment.

Among end portions of the second coupling body 412 in an extending direction, one end portion thereof facing the first coupling body 411, that is, a front end portion thereof in the illustrated embodiment, is continuous with the first coupling body 411. Among the end portions of the second coupling body 412 in the extending direction, the other end portion thereof opposite to the first coupling body 411, a rear end portion thereof in the illustrated embodiment, is continuous with the coupling protrusion 416.

The second coupling body 412 is continuous with the second coupling arm 422. The second coupling body 412 supports the second coupling arm 422 at an upper side.

The second coupling body 412 may have any shape that may be accommodated in the second coupling member accommodation portion 312 and may support the second coupling arm 422. In the illustrated embodiment, the second coupling body 412 is provided in a plate shape that extends in an anteroposterior direction and has a width in a lateral direction and a thickness in a vertical direction.

In this case, a length of the second coupling body 412 in a width direction, that is, a length thereof in a lateral direction, may be formed to be less than a length of the first coupling body 411 in a width direction.

The second coupling body 412 is surrounded by the support arm 440. That is, as will be described below, the second coupling body 412 is positioned between a pair of support arms 440 and spaced apart from each of support arms 441 and 442.

The pressing protrusion 413 is formed to protrude from an upper side of the first coupling body 411. A worker may press the pressing protrusion 413 to couple the coupling member 400 to the coupling member attachment-detachment portion 300. As described above, in an embodiment in which the coupling member 400 and the coupling member attachment-detachment portion 300 are hook-fitted to each other, an external force for hook fitting may be applied to the pressing protrusion 413.

In addition, when the power electronic device 20 is coupled to the terminal member 10, the pressing protrusion 413 protrudes outward. A worker may press the pressing protrusion 413 to release a coupling state between the support member 140 and the coupling arm 420 and then may separate the power electronic device 20 from the terminal member 10.

The pressing protrusion 413 is continuous with the first coupling body 411. In the illustrated embodiment, a front lower side of the pressing protrusion 413 is continuous with the first portion of the first coupling body 411, and a rear lower side of the pressing protrusion 413 is continuous with the second portion of the first coupling body 411. The pressing protrusion 413 is positioned to cover the guide portion 430 positioned between the first portion and the second portion of the first coupling body 411 at an upper side.

The pressing protrusion 413 may be formed to have a width that is equal to that of the first coupling body 411. A weight-reducing groove 413a is formed to be recessed in an upper side of the pressing protrusion 413 so that the convenience of processing the pressing protrusion 413 can be improved. In addition, due to the weight-reducing groove 413a, a frictional force of the upper side of the pressing protrusion 413 is increased so that a process of coupling the coupling member 400 to the coupling member attachment-detachment portion 300 and a process of separating the power electronic device 20 from the terminal member 10 can be easily performed.

The pressing groove 414 is formed to be recessed into the coupling protrusion 416. When the coupling member 400 is to be separated from the coupling member attachment-detachment portion 300, the coupling protrusion 416 is pressed toward the first coupling body 411, that is, forward in the illustrated embodiment. In this case, since the pressing groove 414 is formed, a frictional force generated on a surface of the coupling protrusion 416 may increase so that a magnitude of an external force to needs to be applied by a worker may decrease.

That is, the pressing groove 414 increases a frictional force of the coupling protrusion 416, thereby allowing a worker to easily grip and press the coupling protrusion 416.

The pressing groove 414 is formed to be recessed in one surface opposite to the first coupling body 411 among surfaces of the coupling protrusion 416, that is, a rear surface thereof in the illustrated embodiment. As will be described below, the one surface is defined as the second support surface 416b.

The plate accommodation groove 415 is a space formed inside the first coupling body 411. The first guide plate 331 and the second guide plate 332 of the member guide portion 330 are accommodated in the plate accommodation groove 415 to be withdrawable.

The plate accommodation groove 415 is partially surrounded by the first coupling body 411 and the pressing protrusion 413. In the illustrated embodiment, a front side of the plate accommodation groove 415 is surrounded by the first portion of the first coupling body 411, and a rear side of the plate accommodation groove 415 is surrounded by the second portion of the first coupling body 411. An upper side of the plate accommodation groove 415 is covered by the pressing protrusion 413.

A lower side of the plate accommodation groove 415 may be formed to be open so that the first guide plate 331 and the second guide plate 332 may be withdrawably accommodated therein. Outer sides of the plate accommodation groove 415 in a width direction, that is, a left side and a right side thereof in the illustrated embodiment, communicate with the outside by the first guide groove 431a and the second guide groove 431b.

Accordingly, it will be understood that the guide plates 331 and 332 accommodated in the plate accommodation grooves 415 are also movably inserted into the guide grooves 431a and 431b, respectively.

The guide rib 432 is positioned inside the plate accommodation groove 415. The guide rib 432 is inserted into the rib accommodation portion 333 formed between a plurality of guide plates 331 and 332.

The coupling protrusion 416 is a portion through which the coupling member 400 is coupled to the support member 140 of the terminal member 10. The coupling protrusion 416 may be hook-fitted to the second extension arm 142 of the support member 140.

The coupling protrusion 416 is continuous with the second coupling body 412. Specifically, the coupling protrusion 416 is continuous with the other end portion of the second coupling body 412 opposite to the first coupling body 411 among the end portions of the second coupling body 412 in the extending direction, that is, the rear end portion thereof in the illustrated embodiment.

The coupling protrusion 416 may be formed to protrude further than the second coupling body 412. Due to the protrusion, the coupling protrusion 416 may be hook-fitted to the second extension arm 142. In the illustrated embodiment, the coupling protrusion 416 is formed to protrude upward further than the second coupling body 412.

The coupling protrusion 416 may be formed to have a width that is equal to that of the second coupling body 412. In other words, the coupling protrusion 416 is formed to have a width that is less than a width of the first coupling body 411. Accordingly, the coupling protrusion 416 is positioned between a plurality of support arms 440 to be spaced apart from the support arms 440.

The coupling protrusion 416 may include a plurality of surfaces. Respective surfaces may be continuous with and form a predetermined angle with each other. In the illustrated embodiment, the coupling protrusion 416 includes the first support surface 416a and the second support surface 416b.

The first support surface 416a forms one surface facing the first coupling body 411 among the surfaces of the coupling protrusion 416, that is, a front surface in the illustrated embodiment. The first support surface 416a is continuous with the second coupling body 412.

The first support surface 416a extends to form a predetermined angle with the second coupling body 412. In the illustrated embodiment, the first support surface 416a forms an obtuse angle with the upper surface of the second coupling body 412 and extends obliquely in a direction opposite to the first coupling body 411. In other words, the first support surface 416a obliquely extends downwardly forward and upwardly rearward.

When the coupling member 400 is coupled to the support member 140, the first support surface 416a comes into contact with the fifth extension surface 142e of the second extension arm 142. That is, the first support surface 416a is in contact with and supported by the fifth extension surface 142e. For this purpose, the first support surface 416a and the fifth extension surface 142e may extend to have the same inclination.

The first support surface 416a is continuous with the second support surface 416b through an upper surface of the coupling protrusion 416.

The second support surface 416b forms the other surface opposite to the first coupling body 411 among the surfaces of the coupling protrusion 416, that is, the rear surface in the illustrated embodiment. The second support surface 416b is continuous with the first support surface 416b.

The second support surface 416b extends to form a predetermined angle with the upper surface of the coupling protrusion 416. In the illustrated embodiment, the second support surface 416b forms an obtuse angle with the upper surface of the coupling protrusion 416 and obliquely extends in a direction opposite to the first coupling body 411. In other words, the second support surface 416b obliquely extends upwardly forward and downwardly rearward.

When the coupling member 400 moves toward the support member 140, the second support surface 416b comes into contact with the third extension surface 142c of the second extension arm 142. As the coupling member 400 moves, the second extension arm 142 moves toward an upper side of the coupling protrusion 416 along the second support surface 416b and enters a space between the first support surface 416a and the first coupling body 411. Accordingly, the coupling member 400 and the support member 140 may be hook-fitted to each other.

For this purpose, the second support surface 416b and the third extension surface 142c may be formed to have the same inclination.

The coupling arm 420 is a portion through which the coupling member 400 is coupled to the coupling member attachment-detachment portion 300. The coupling arm 420 may be detachably coupled to the coupling member attachment-detachment portion 300. Accordingly, the coupling member 400 and the housing 200 may be hook-fitted to each other.

The coupling arm 420 is continuous with the coupling body 410. The coupling arm 420 is continuous with one side of the coupling body 410 facing the coupling member attachment-detachment portion 300 among respective sides of the coupling body 410, that is, a lower end portion thereof in the illustrated embodiment.

A plurality of coupling arms 420 may be provided. Each of the plurality of coupling arms 420 is connected to one of the first coupling body 411 and the second coupling body 412 and passes through and is coupled to one of the plurality of coupling openings 320.

In the illustrated embodiment, the coupling arm 420 includes the first coupling arm 421 and the second coupling arm 422.

The first coupling arm 421 is continuous with the first coupling body 411 and passes through and is coupled to the first coupling opening 321. The first coupling arm 421 is detachably coupled to an inner upper surface of the second housing 220 of an outer periphery of the first coupling opening 321.

The first coupling arm 421 is continuous with the first portion of the first coupling body 411, that is, a lower end portion of a front portion thereof. The first coupling arm 421 is formed to extend in a height direction of the first coupling body 411, that is, a vertical direction in the illustrated embodiment.

The first coupling arm 421 may be formed to have a width that is less than the width of the first coupling body 411. In addition, the first coupling arm 421 may be formed to have a length that is less than a length of the first coupling opening 321 in a width direction, that is, a length thereof in a lateral direction.

In the illustrated embodiment, the first coupling arm 421 includes a first coupling extension portion 421a and a first coupling protrusion 421b.

The first coupling extension portion 421a is a portion through which the first coupling arm 421 is continuous with the first coupling body 411. The first coupling extension portion 421a passes through the first coupling opening 321.

The first coupling extension portion 421a extends downward from a lower end portion of the first coupling body 411. One end portion of the first coupling extension portion 421a in an extending direction, that is, an upper end portion thereof in the illustrated embodiment, is continuous with the first portion of the first coupling body 411. The first coupling protrusion 421b is positioned at the other end portion of the first coupling extension portion 421a in the extending direction, that is, a lower end portion thereof in the illustrated embodiment.

The first coupling protrusion 421b is a portion through which the first coupling arm 421 is hook-fitted to the coupling member attachment-detachment portion 300. The first coupling protrusion 421b is formed at the other end portion of the first coupling extension portion 421a, that is, the lower end portion thereof in the illustrated embodiment.

The first coupling protrusion 421b is formed to protrude outward from the first coupling extension portion 421a. In the illustrated embodiment, the first coupling protrusion 421b is formed to protrude forward. In this case, the first coupling protrusion 421b includes a first portion extending horizontally and a second portion that is continuous with the first portion and obliquely extends downward toward the first coupling extension portion 421b.

The first coupling arm 421 may be pressed inward, that is, rearward in the illustrated embodiment, and the first coupling arm 421 may pass through the first coupling opening 321. In this case, the first portion may come into contact with the outer periphery of the first coupling opening 321 and may be pressed rearward.

When the first coupling protrusion 421b completely passes through the first coupling opening 321, a pressed state may be released, and the first coupling arm 421 may be moved forward. In this case, the second portion comes into contact with a surface of the outer periphery of the first coupling opening 321 which is positioned inside the second housing 220. Accordingly, hook fitting between the first coupling arm 421 and the coupling member attachment-detachment portion 300 is completed.

The second coupling arm 422 is continuous with the second coupling body 412 and passes through and is coupled to the second coupling opening 322. The second coupling arm 422 is detachably coupled to the inner upper surface of the second housing 220 of the outer periphery of the second coupling opening 322.

The second coupling arm 422 is continuous with a lower end portion of the second coupling body 412. The second coupling arm 422 is formed to extend in a height direction of the second coupling body 412, that is, a vertical direction in the illustrated embodiment.

The second coupling arm 422 may be formed to have a width that is less than a width of the second coupling body 412. In the illustrated embodiment, the second coupling arm 422 may be formed to have a length that is less than or equal to a length of the second coupling opening 322 in a width direction, that is, a length thereof in a lateral direction.

In the illustrated embodiment, the second coupling arm 422 includes a second coupling extension portion 422a and a second coupling protrusion 422b.

The second coupling extension portion 422a is a portion of the second coupling arm 422 continuous with the second coupling body 412. The second coupling extension portion 422a passes through the second coupling opening 322.

The second coupling extension portion 422a extends downward from the lower end portion of the second coupling body 412. One end portion of the second coupling extension portion 422a in an extending direction, that is, an upper end portion thereof in the illustrated embodiment, is continuous with the second coupling body 412. The second coupling protrusion 421b is positioned at the other end portion of the second coupling extension portion 422a in the extending direction, that is, a lower end portion thereof in the illustrated embodiment.

The second coupling protrusion 422b is a portion through which the second coupling arm 422 is hook-fitted to the coupling member attachment-detachment portion 300. The second coupling protrusion 422b is formed at the other end portion of the second coupling extension portion 422a, that is, the lower end portion thereof in the illustrated embodiment.

The second coupling protrusion 422b is formed to protrude outward from the second coupling extension portion 422a. In the illustrated embodiment, the second coupling protrusion 422b is formed to protrude rearward. In this case, the second coupling protrusion 422b includes a first portion extending horizontally and a second portion that is continuous with the first portion and obliquely extends downward toward the second coupling extension portion 422a.

The second coupling arm 422 may be pressed inward, that is, forward in the illustrated embodiment, and the second coupling arm 422 may pass through the second coupling opening 322. In this case, the second portion may come into contact with an outer periphery of the second coupling opening 322 and may be pressed forward.

When the second coupling protrusion 422b completely passes through the second coupling opening 322, a pressed state may be released, and the second coupling arm 422 may be moved forward. In this case, the second portion comes into contact with a surface of the outer periphery of the second coupling opening 322 which is positioned inside the second housing 220. Accordingly, hook fitting between the second coupling arm 422 and the coupling member attachment-detachment portion 300 is completed.

Accordingly, the coupling member 400 may be hook-fitted to the coupling member attachment-detachment portion 300 by the plurality of coupling arms 420. In this case, due to shapes of the coupling protrusions 421b and 422b, a worker may couple the coupling member 400 and the coupling member attachment-detachment portion 300 simply by pressing the coupling member 400 against the coupling member attachment-detachment portion 300.

In addition, due to the shapes of the coupling protrusions 421b and 422b, the coupling member 400 and the coupling member attachment-detachment portion 300 are hook-fitted to each other. Accordingly, unless an external force in a preset direction is applied, a coupling state between the coupling member 400 and the coupling member attachment-detachment portion 300 can be stably maintained.

In addition, the first coupling arm 421 and the second coupling arm 422 may be formed symmetrically in an anteroposterior direction. Accordingly, the processability of the coupling member 400 can be improved. In addition, the coupling and separation between the coupling member 400 and the housing 200 can be easily performed. Furthermore, the coupling member 400 coupled to the housing 200 is prevented from shaking in any direction, particularly in an anteroposterior direction in which the first coupling arm 421 and the second coupling arm 422 are spaced apart from each other.

The guide portion 430 guides the coupling member 400 to be coupled to the coupling member attachment-detachment portion 300 in a preset direction. The guide portion 430 is movably coupled to the member guide portion 330 of the coupling member attachment-detachment portion 300. The coupling member 400 and the coupling member attachment-detachment portion 300 may be coupled to or separated from each other in a state in which the guide portion 430 and the member guide portion 330 are coupled.

The guide portion 430 is continuous with the coupling body 410. Specifically, the guide portion 430 is positioned at one side of the coupling body 410 facing the coupling member attachment-detachment portion 300 among the respective sides of the coupling body 410, that is, a lower side thereof in the illustrated embodiment. The guide portion 430 is positioned between the first portion (that is, a front portion) and the second portion (that is, a rear portion) of the first coupling body 411.

In the illustrated embodiment, the guide portion 430 includes the guide groove 431 and the guide rib 432.

The guide groove 431 is a space into which the guide plates 331 and 332 of the member guide portion 330 are movably inserted. The guide groove 431 is formed to extend in an extending direction of the guide plates 331 and 332, that is, a vertical direction in the illustrated embodiment.

The guide groove 431 is formed in the first coupling body 411. In the illustrated embodiment, the guide groove 431 is formed in a width direction of the first coupling body 411, that is, at left and right sides. The guide groove 431 is formed to pass through each of a left surface and a right surface of the first coupling body 411.

The guide groove 431 is connected to the plate accommodation groove 415. Portions of the guide plates 331 and 332 may be accommodated in the plate accommodation groove 415, and other portions of the guide plates 331 and 332 may be movably inserted into the guide groove 431.

The guide groove 431 may be formed to have a length that is greater than a thickness of each of the guide plates 331 and 332, that is, a length thereof in an anteroposterior direction.

A plurality of guide grooves 431 may be provided. The plurality of guide grooves 431 are formed at different positions of the first coupling body 411 to movably accommodate different guide plates 331 and 332.

In the illustrated embodiment, the guide groove 431 includes the first guide groove 431a and the second guide groove 431b.

The first guide groove 431a is formed to pass through the left surface of the first coupling body 411. The first guide plate 331 is movably insertion-coupled to the first guide groove 431a.

The second guide groove 431b is formed to pass through the right surface of the first coupling body 411. The second guide plate 332 is movably insertion-coupled to the second guide groove 431b.

The guide rib 432 is formed between the first guide groove 431a and the second guide groove 431b.

The guide rib 432 is movably inserted into the rib accommodation portion 333 of the member guide portion 330. The guide rib 432 is formed to extend in the extending direction of the guide plates 331 and 332, that is, a vertical direction in the illustrated embodiment.

The guide rib 432 is continuous with the first coupling body 411. In the illustrated embodiment, the guide rib 432 is formed to protrude forward from a front surface of the second portion of the first coupling body 411.

The guide rib 432 may extend by a height that is less than a height of the first coupling body 411. In this case, one end portion of the guide rib 432 in an extending direction, a lower end portion thereof in the illustrated embodiment, may be positioned at the same level as a lower end portion of the second portion of the first coupling body 411.

Accordingly, the second portion of the first coupling body 411 and the guide rib 432 may be seated together on a portion surrounding the second coupling opening 322 of the upper surface 222. Accordingly, even when the power electronic device 20 vibrates vertically, a coupling state between the coupling member 400 and the coupling member attachment-detachment portion 300 can be stably maintained.

The guide rib 432 may be formed to have a thickness that is less than or equal to a width of the rib accommodation portion 333. Accordingly, the guide rib 432 may be easily inserted into or withdrawn from the rib accommodation portion 333.

The support arm 440 provides a restoring force to the coupling member 400. When vertical vibrations are generated in the coupling member 400 and the power electronic device 20 connected to the coupling member 400, the support arm 440 is deformed to store a restoring force, thereby buffering shock caused by the generated vibrations.

Accordingly, even when a separate elastic member such as a spring is not provided in the coupling member 400, a coupling state between the power electronic device 20 and the terminal member 10 can be stably maintained.

When the coupling member 400 is coupled to the coupling member attachment-detachment portion 300, the support arm 440 extends downward further than a lower end portion of the coupling body 410. In other words, in a state in which an external force is not applied, the coupling member 400 is supported by the support arm 440 in contact with the upper surface 222, and the coupling body 410 is spaced apart from the upper surface 222.

When vertical vibrations are generated in the above state, the support arm 440 may be deformed, and the coupling member 400 may be lowered so that the coupling body 410 may come into contact with the upper surface 222. In addition, when the vibrations are released, the support arm 440 may be deformed and restored by a stored elastic force, and the coupling body 410 may be spaced apart from the upper surface 222 again.

Accordingly, even when vertical vibrations are generated in the terminal member 10 and the power electronic device 20 coupled thereto, the vibrations may be buffered by the support arm 440. Accordingly, damage to the terminal member 10 and the power electronic device 20 can be prevented. Furthermore, damage to the coupling member 400 connected to each of the terminal member 10 and the power electronic device 20 can be prevented.

The support arm 440 is continuous with the coupling body 410. Specifically, the support arm 440 is continuous with the second portion (that is, a rear portion) of the first coupling body 411. The support arm 440 obliquely extends downwardly rearward from a rear surface of the second portion of the first coupling body 411.

One end portion of the support arm 440 in an extending direction that is, an upper end portion thereof in the illustrated embodiment, is continuous with the second portion of the first coupling body 411. The other end portion of the support arm 440 in the extending direction, that is, a rear lower end portion thereof in the illustrated embodiment, is positioned at a lower level than the lower end portion of the first coupling body 411 and the lower end portion of the second coupling body 412. Through such a structure, the support arm 440 may elastically support the coupling member 400.

The support arm 440 is positioned apart from the second coupling body 412 and the coupling protrusion 416. The support arm 440 partially surrounds the second coupling body 412 and the coupling protrusion 416 at an outer side thereof in a width direction.

The plurality of support arms 440 may be provided. The plurality of support arms 440 may be coupled to the coupling body 410 at different positions and may be in contact with the upper surface 222 at different positions to elastically support the coupling member 400. In the illustrated embodiment, two support arms 440 are provided by including a first support arm 441 and a second support arm 442.

The first support arm 441 and the second support arm 442 are spaced apart from each other and are positioned to face each other with the second coupling body 412 and the coupling protrusion 416 interposed therebetween. In one embodiment, the first support arm 441 and the second support arm 442 may extend by the same length.

The first support arm 441 is continuous with a rear left portion of the first coupling body 411. The first support arm 441 surrounds the second coupling body 412 and the coupling protrusion 416 at a left side and obliquely extends downward. A lower end portion of the first support arm 441 may be positioned at a lower level than a lower end portion of the coupling body 410.

The second support arm 442 is continuous with a rear right portion of the second portion of the first coupling body 411. The second support arm 442 surrounds the second coupling body 412 and the coupling protrusion 416 at a right side and obliquely extends downward. A lower end portion of the second support arm 442 may be positioned at a lower level than the lower end portion of the coupling body 410.

### 5. Description of a Process of Coupling the Terminal Member 10 and the Power Electronic Device 20 According to an Embodiment of the Present Disclosure

The power electronic device 20 according to the embodiment of the present disclosure includes the coupling member 400. The coupling member 400 is detachably coupled to the coupling member attachment-detachment portion 300 of the power electronic device 20. Accordingly, in addition, the coupling member 400 is detachably coupled to the support member 140 of the terminal member 10. In one embodiment, the coupling member 400 may be hook-fitted to each of the coupling member attachment-detachment portion 300 and the support member 140.

A power electronic device according to the related art is coupled directly to a terminal member through a component that is provided integrally with the power electronic device itself. Therefore, there was a problem in that, when the component was damaged, the entire cover of the power electronics had to be replaced.

In addition, in general, various devices accommodated inside the power electronic device according to the related art are also provided integrally with the cover. Therefore, there was a problem in that the device inside had to be disassembled when the cover was replaced.

Accordingly, excessive time and costs were required to maintain the component coupling the power electronic and the terminal member. In addition, there was concern that, during a process of disassembling electrical components that did not require maintenance, unintended damage to the electrical components would occur.

On the other hand, when the coupling member 400 according to the embodiment of the present disclosure is damaged, a maintenance operation can be completed by replacing only the coupling member 400. Accordingly, the time and costs required for maintenance can be reduced, and the durability and operational reliability of the power electronic device 20 can be improved because a coupling state of sensitive electrical components is not destroyed.

Furthermore, the coupling member 400 is elastically supported by the support arm 440. Therefore, vibrations generated by the operations of the power electronic device 20 and the terminal member 10 may be buffered by the coupling member 400. Accordingly, damage to the components of the power electronic device 20 due to the vibrations can be prevented. Furthermore, since a separate elastic member is not required to buffer vibrations, assembly efficiency can be improved, and manufacturing costs can be reduced.

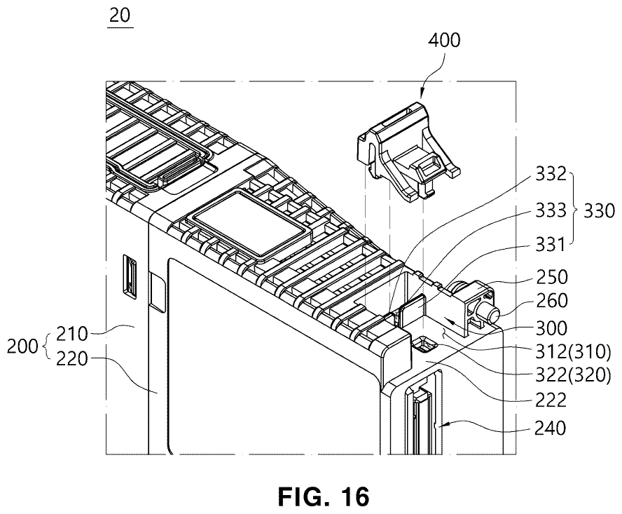

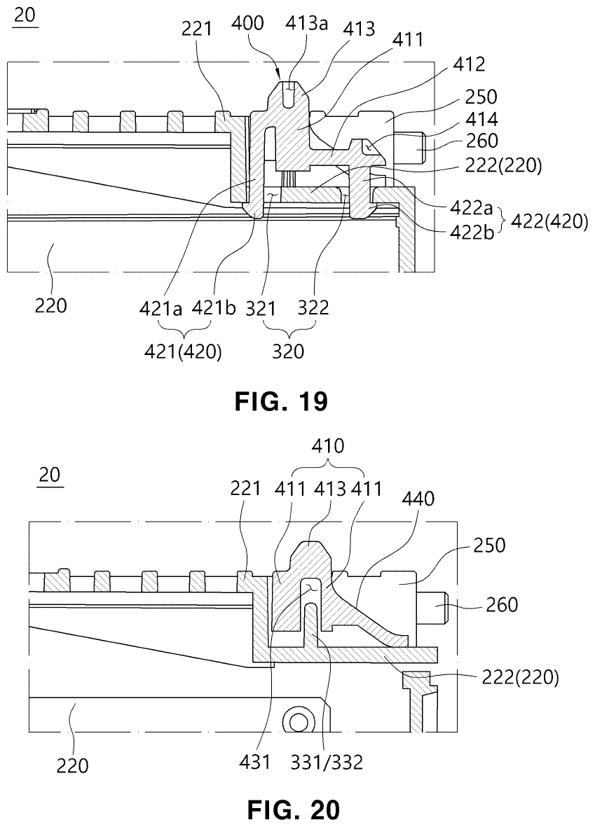

Hereinafter, a process of coupling the power electronic device 20 and the terminal member 10 according to an embodiment of the present disclosure and a coupling state will be described in detail with reference to FIGS. 16 to 23.

### (1) Description of the Process of Coupling the Power Electronic Device 20 and the Coupling Member 400 According to the Embodiment of the Present Disclosure

Referring to FIGS. 16 to 20, a process in which the coupling member 400 is coupled to the coupling member attachment-detachment portion 300 of the power electronic device 20 according to an embodiment of the present disclosure and a coupling state are shown.

Referring to FIG. 16, the coupling member 400 is moved from an upper side to a lower side and coupled to the coupling member attachment-detachment portion 300. As described above, the front side, the left side, and the right side of the coupling member attachment-detachment portion 300 are surrounded by the second frame 221, the lower side thereof is surrounded by the upper surface 222, and the upper side and the rear side thereof are open. The coupling member 400 is coupled to the coupling member attachment-detachment portion 300 through the upper side.

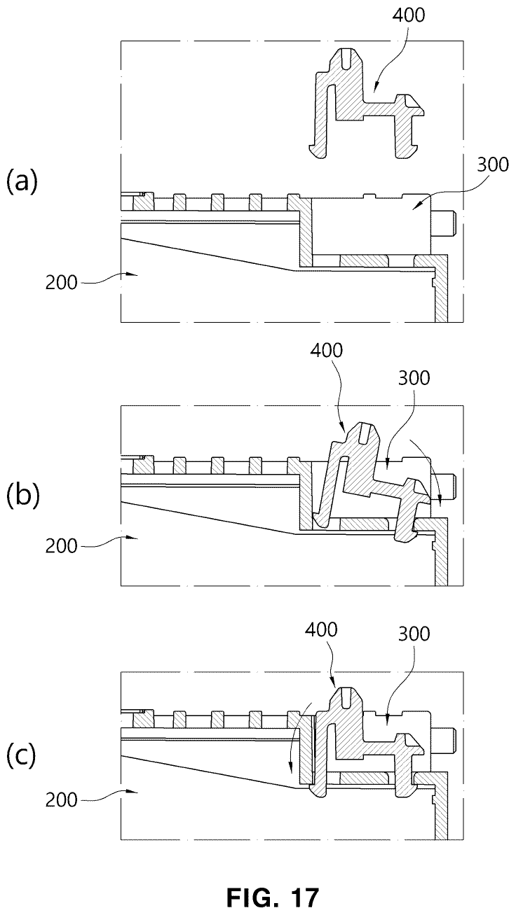

Referring to FIG. 17, a process in which the coupling member 400 is coupled to the coupling member attachment-detachment portion 300 is shown.

Referring to FIG. 17A, the coupling member 400 is positioned above the coupling member attachment-detachment portion 300. In this case, the first coupling arm 421 is disposed above the first coupling opening 321, and the second coupling arm 422 is disposed above the second coupling opening 322.

Referring to FIG. 17B, the second coupling arm 422 is first inserted into the second coupling opening 322. In the illustrated embodiment, the coupling member 400 is rotated clockwise so that the second coupling arm 422 at a rear side is first inserted into the second coupling opening 322 at a rear side.

Referring to FIG. 17C, the first coupling arm 421 is inserted into the first coupling opening 321. In the illustrated embodiment, the coupling member 400 is rotated counterclockwise so that the first coupling arm 421 at a front side is inserted into the first coupling opening 321 at a front side.

In this case, the member guide portion 330 and the guide portion 430 may also be movably coupled so that accurate coupling between the coupling member 400 and the coupling member attachment-detachment portion 300 may be guided.

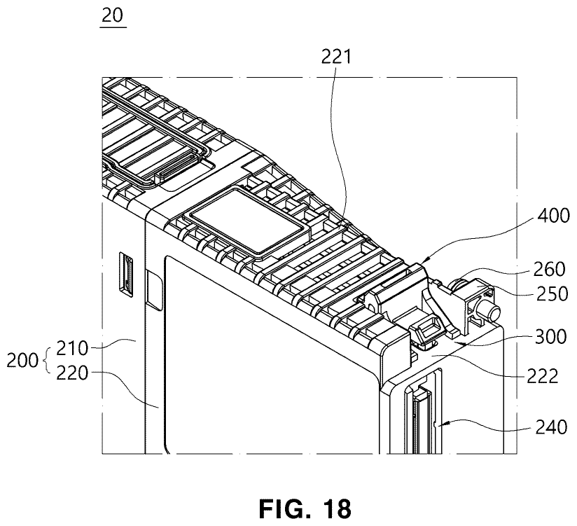

Referring to FIGS. 18 to 20, a state in which the coupling member 400 is coupled to the coupling member attachment-detachment portion 300 is shown.

First, the first coupling arm 421 passes through the first coupling opening 321 so that the first coupling protrusion 421b is hook-fitted to a front side of an upper inner surface of the second housing 220. Likewise, the second coupling arm 422 passes through the second coupling opening 322 so that the second coupling protrusion 422b is hook-fitted to a rear side of the upper inner surface of the second housing 220.

Accordingly, arbitrary separation of the coupling member 400 and the coupling member attachment-detachment portion 300 can be prevented.

The first guide plate 331 and the second guide plate 332 are inserted into the first guide groove 431a and the second guide groove 431b to be vertically movable, respectively. In addition, the guide rib 432 is inserted into the rib accommodation portion 333 to be vertically movable.

Therefore, the anteroposterior and lateral movements of the coupling member 400 are limited by coupling between the member guide portion 330 and the guide portion 430.

In this case, the coupling member 400 is elastically supported by the support arm 440 that is in contact with the upper surface 222. That is, the components of the coupling member 400 other than a lower end portion of the support arm 440 are spaced apart from the upper surface 222.

Accordingly, even when vibrations are generated in the power electronic device 20, shock caused by the generated vibrations can be mitigated by an elastic force applied by the support arm 440.

### (2) Description of a Process of Coupling the Terminal Member 10 and the Power Electronic Device 20 According to an Embodiment of the Present Disclosure

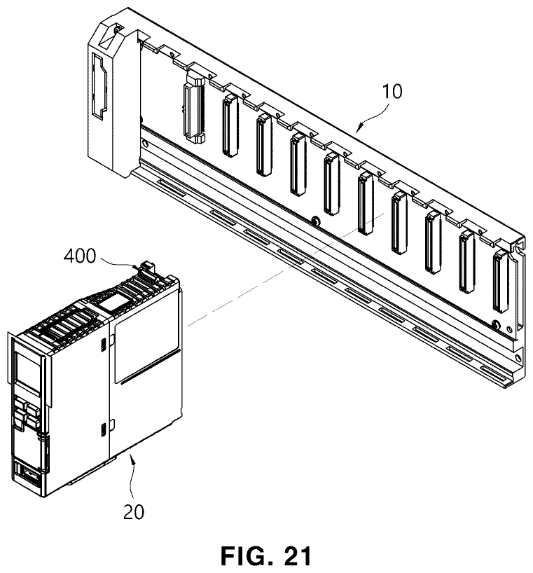

Referring to FIGS. 21 to 23, the process of coupling the power electronic device 20 and the terminal member 10 according to the embodiment of the present disclosure, and a coupling state are shown. In the illustrated embodiment, it will be understood that the coupling member 400 is detachably coupled to the power electronic device 20.

Referring to FIG. 21, the power electronic device 20 is moved from a front side to a rear side and coupled to the terminal member 10. In this case, a protrusion (not shown) formed at a lower side of the second housing 220 overlaps the base groove 131, the terminal member 240 overlaps the slot member 120, the fastening support portion 250 overlaps the fastening hole 160, and the coupling member 400 overlaps the support member 140 in an anteroposterior direction.

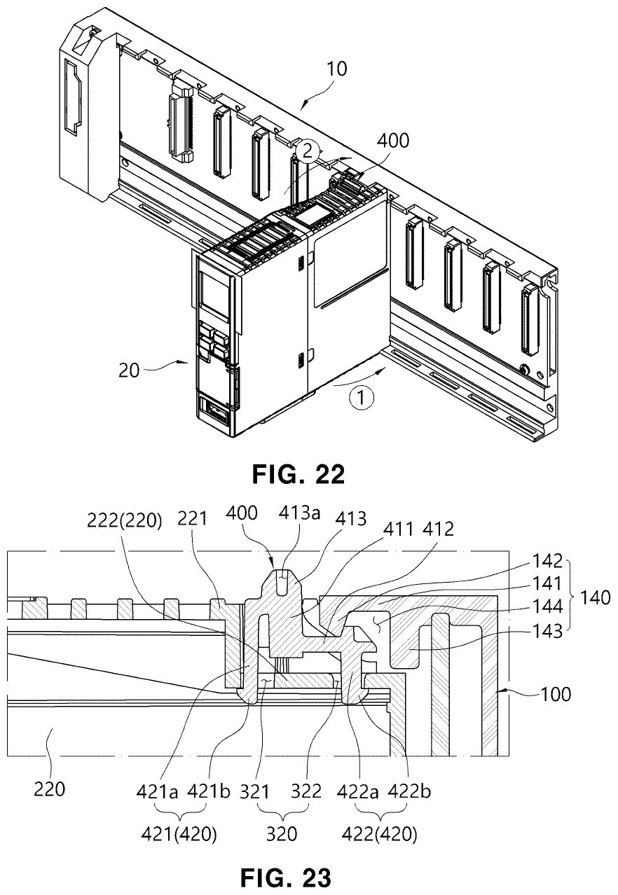

Referring to FIG. 22, the order in which the power electronic device 20 is coupled to the terminal member 10 is shown. In the illustrated embodiment, the power electronic device 20 is rotated counterclockwise so that the protrusion (not shown) formed at the lower side of the second housing 220 is first inserted into the base groove 131 (see \textcircled{1} in FIG. 22).

Next, the power electronic device 20 is rotated clockwise so that the terminal member 240 is coupled to the slot member 120, and the coupling member 400 is coupled to the support member 140 (see \textcircled{2} of FIG. 22). Although not shown, a process in which the fastening member 260 is coupled to each of the fastening support portion 250 and the fastening hole 160 may be further performed.

Referring to FIG. 23, a state in which the power electronic device 20 is coupled to the terminal member 10 is shown.

The coupling protrusion 416 presses the second extension arm 142 upward and moves rearward. In this case, the third extension surface 142c comes into contact with the second support surface 416b and moves upward along the second support surface 416b.

When the movement of the power electronic device 20 is completed, the second extension arm 142 is accommodated in a space formed between the coupling protrusion 416 and the first coupling body 411. In this case, the fifth extension surface 142e comes into contact with the first support surface 416a.

In such a state, the support member 140 presses the coupling member 400 downward due to a shape thereof. In addition, the coupling member 400 is pressed upward by an elastic force applied by the support arm 440. Accordingly, the power electronic device 20 and the terminal member 10 may be stably hook-fitted to each other.

In such a state, when the power electronic device 20 is to be separated from the terminal member 10, the pressing protrusion 413 is pressed to compress the support arm 440 and move the coupling member 400 downward. Accordingly, when the support member 140 is separated from the coupling member 400, the power electronic device 20 may be moved forward and separated from the terminal member 10.

While the present disclosure has been described with reference to embodiments thereof, the spirit of the present disclosure is not limited to the embodiments presented in the present specification. Those skilled in the art who understand the spirit of the present disclosure may easily suggest other embodiments by adding, changing, or deleting components within the scope of the same concept, and the other embodiments are also within the spirit of the present disclosure.

| | |
|---|---|
| 10: terminal member | 20: power electronic device |
| 100: terminal body | 110: conductive member |
| 120: slot member | 130: support base |
| 131: base groove | 140: support member |
| 141: first extension arm | 142: second extension arm |
| 142a: first extension surface | 142b: second extension surface |
| 142c: third extension surface | 142d: fourth extension surface |
| 142e: fifth extension surface | 143: third extension arm |
| 144: member accommodation portion | 150: device accommodation portion |
| 160: fastening hole | 200: housing |
| 210: first housing | 211: first frame |
| 220: second housing | 221: second frame |
| 222: upper surface | 230: manipulation portion |
| 240: terminal member | 250: fastening support portion |
| 260: fastening member | 300: coupling member attachment-detachment portion |
| 310: coupling member accommodation portion | 311: first coupling member accommodation portion |
| 312: second coupling member accommodation portion | 320: coupling opening |
| 321: first coupling opening | 322: second coupling opening |
| 330: member guide portion | 331: first guide plate |
| 332: second guide plate | 333: rib accommodation portion |
| 400: coupling member | 410: coupling body |
| 411: first coupling body | 412: second coupling body |
| 413: pressing protrusion | 413a: weight-reducing groove |
| 414: pressing groove | 415: plate accommodation groove |
| 416: coupling protrusion | 416a: first support surface |
| 416b: second support surface | 420: coupling arm |
| 421: first coupling arm | 421a: first coupling extension portion |
| 421b: first coupling protrusion | 422: second coupling arm |
| 422a: second coupling extension portion | 422b: second coupling protrusion |
| 430: guide portion | 431: guide groove |
| 431a: first guide groove | 431b: second guide groove |
| 432: guide rib | 440: support arm |
| 441: first support arm | 442: second support arm |

1. A coupling member detachably connected to an external power electronic device, comprising:
a coupling body; and
a coupling arm which extends from one side of the coupling body in a height direction and is detachably coupled to the power electronic device,
wherein the coupling arm includes a coupling extension portion extending from the one side of the coupling body to an interior of the power electronic device, and a coupling protrusion protruding from an end portion of the coupling extension portion and coupled to an inner surface of the power electronic device, and
the coupling arm is provided as a plurality of coupling arms, wherein the plurality of coupling arms are disposed apart from each other in one direction.

2. The coupling member of claim 1, wherein the coupling arm includes:
a first coupling arm positioned to be biased to one side of the coupling body in a length direction; and
a second coupling arm positioned to be biased to the other side opposite to the one side of the coupling body in the length direction.

3. The coupling member of claim 2, wherein the first coupling protrusion of the first coupling arm protrudes toward the one side in the length direction, and
the second coupling protrusion of the second coupling arm protrudes toward the other side in the length direction.

4. The coupling member of claim 1, wherein the coupling arm is hook-fitted to the power electronic device.

5. The coupling member of claim 1, comprising a support arm which obliquely extends from the one side of the coupling body in a length direction toward the power electronic device and of which an end portion in an extending direction thereof is positioned to protrude further than an end portion of the one side of the coupling body in the height direction to elastically support the coupling body.

6. The coupling member of claim 5, wherein the support arm includes:
a first support arm positioned to be biased to one side of the coupling body in a width direction; and
a second support arm disposed apart from the first support arm and positioned to be biased to the other side of the coupling body in the width direction.

7. The coupling member of claim 1, comprising:
a plurality of guide grooves formed to pass through each side surface of the coupling body in a width direction to movably accommodate guide plates provided in the power electronic device; and
a guide rib which is positioned between the plurality of guide grooves, extends from an interior of the coupling body in the height direction of the coupling body, and is inserted into a rib accommodation portion provided in the power electronic device.

8. The coupling member of claim 1, wherein the coupling body includes:
a first coupling body extending in the height direction;
a second coupling body which is continuous with one side of the first coupling body in a length direction and extends in the length direction; and
a coupling protrusion which is positioned at an end portion of the second coupling body and protrudes to the other side in the height direction.

9. The coupling member of claim 8, wherein the coupling protrusion includes a first support surface obliquely extending to the other side in the height direction, and a second support surface which is continuous with the first support surface and obliquely extends to the one side in the height direction, and
the coupling body includes a pressing groove formed to be recessed in the second support surface.

10. A power electronic device comprising:
a housing having a space formed therein;
a coupling member attachment-detachment portion positioned at a rear upper side of the housing; and
a coupling member detachably coupled to the coupling member attachment-detachment portion,
wherein the coupling member attachment-detachment portion includes a coupling member accommodation portion of which an upper side and a rear side are open and which is partially surrounded by an upper surface of the housing, and a coupling opening formed to pass through the upper surface of the housing, and
the coupling member includes a coupling body accommodated in the coupling member accommodation portion, and a coupling arm which extends from a lower side of the coupling body and passes through and is coupled to the coupling opening.

11. The power electronic device of claim 10, wherein the coupling opening includes a first coupling opening positioned to be biased to a front side of the coupling member accommodation portion, and a second coupling opening positioned to be biased to a rear side of the coupling member accommodation portion, and
the coupling arm includes a first coupling arm which is positioned to be biased to a front side of the coupling body and passes through the first coupling opening, and a second coupling arm which is positioned to be biased to a rear side of the coupling body and passes through the second coupling opening.

12. The power electronic device of claim 11, wherein the first coupling arm includes a first coupling extension portion which is continuous with the coupling body and passes through the first coupling opening, and a first coupling protrusion which is positioned at an end portion of the first coupling extension portion, is formed to protrude forward, and is coupled to an upper inner surface of the housing, and
the second coupling arm includes a second coupling extension portion which is continuous with the coupling body and passes through the second coupling opening, and a second coupling protrusion which is positioned at an end portion of the second coupling extension portion is formed to protrude rearward, and is coupled to the upper inner surface of the housing.

13. The power electronic device of claim 10, wherein the coupling member includes a support arm which is continuous with a rear side of the coupling body, obliquely extends downwardly rearward such that a lower end portion thereof protrudes downward further than a lower end portion of the coupling body, and elastically supports the coupling body,
the coupling body is spaced apart from the upper surface of the housing, and
the support arm is in contact with the upper surface of the housing.

14. The power electronic device of claim 10, wherein the coupling member attachment-detachment portion includes a guide plate which vertically protrudes, laterally extends, and is formed to have a thickness in an anteroposterior direction, and
the coupling member includes a guide groove formed to pass through a surface of the coupling body in a lateral direction, vertically extends, and movably accommodates the guide plate.

15. The power electronic device of claim 14, wherein the guide plate includes a first guide plate positioned to be biased to one side in the lateral direction, and a second guide plate positioned to be biased to the other side in the lateral direction and positioned apart from the first guide plate, and
the guide groove includes a first guide groove formed to vertically pass through a left surface of the coupling body to movably accommodate the first guide plate, and a second guide groove formed to vertically pass through a right surface of the coupling body to movably accommodate the second guide plate.

16. The power electronic device of claim 15, wherein the coupling member attachment-detachment portion includes a rib accommodation portion formed between the first guide plate and the second guide plate, and
the coupling member includes a plate accommodation groove which is formed to be recessed in a lower side of the coupling body, accommodates the first guide plate and the second guide plate, and communicates with the first guide groove and the second guide groove, and a guide rib which is positioned in the plate accommodation groove, extends in an anteroposterior direction and a vertical direction, and is accommodated in the rib accommodation portion.

17. The power electronic device of claim 10, wherein the coupling body includes:
a first coupling body that extends vertically;
a second coupling body which is continuous with the first coupling body and extends in an anteroposterior direction; and
a coupling protrusion which is positioned at a rear end portion of the second coupling body, protrudes upward, and is coupled to a support member provided in an external terminal member.

18. The power electronic device of claim 17, wherein the coupling protrusion includes a first support surface which forms a front surface thereof and obliquely extends upwardly rearward, and a second support surface which forms a rear surface thereof, is continuous with the first support surface, and obliquely extends downwardly rearward, and
the support member of the terminal member includes a first extension arm extending forward, and a second extension arm which is positioned at a front end portion of the first extension arm, protrudes toward the coupling protrusion, and is hook-fitted to the coupling protrusion.

19. The power electronic device of claim 18, wherein the coupling body includes a pressing groove formed to be recessed in the second support surface.

20. The power electronic device of claim 10, wherein the coupling body includes:
a first coupling body that extends vertically; and
a pressing protrusion formed to protrude upward from an upper end portion of the first coupling body,
wherein the pressing protrusion is exposed to the outside of a support member provided in an external terminal member and hook-fitted to the coupling member.
